(19) United States
(12) Patent Application Publication
(10) Pub. No.: US 2026/0033164 A1
(43) Pub. Date: Jan. 29, 2026

(54) DISPLAY PANEL

(71) Applicants: Beijing BOE Technology Development Co., Ltd., Beijing (CN); BOE Technology Group Co., Ltd., Beijing (CN)

(72) Inventors: Tianmin ZHOU, Beijing (CN); Shunhang ZHANG, Beijing (CN); Jiahui HAN, Beijing (CN); Jinchao ZHANG, Beijing (CN); Lizhong WANG, Beijing (CN); Ce NING, Beijing (CN); Guangcai YUAN, Beijing (CN); Xue DONG, Beijing (CN); Hui GUO, Beijing (CN)

(21) Appl. No.: 18/997,463

(22) PCT Filed: May 14, 2024
(86) PCT No.: PCT/CN2024/093227

§ 371 Date: Jan. 21, 2025

(30) Foreign Application Priority Data
Jun. 2, 2023 (CN) 202310653873.1

(51) Int. Cl. H10K 59/124; H10K 59/12; H10K 59/123; H10K 59/131

(52) U.S. Cl. CPC H10K 59/124; H10K 59/1201; H10K 59/123; H10K 59/1315

(57) ABSTRACT

A display panel, a display apparatus, and a manufacturing method for a display panel. The display panel is provided with a display area and a non-display area located on the periphery of the display area, the display area is provided with light-transmitting areas. The display panel includes: a substrate; a first transistor located in the display area on one side of the substrate and includes a first active layer; a first electrode located on the side of the first active layer that faces away from the substrate; and a first insulating layer located between the first active layer and the first electrode, comes into contact with the first electrode, and is provided with a first via hole that penetrates the first insulating layer, the orthographic projection of the first via hole on the substrate is located in the orthographic projection of the light-transmitting areas on the substrate.

### CROSS-REFERENCE TO RELATED APPLICATIONS

This application is a National Stage of International Application No. PCT/CN2024/093227, filed on May 15, 2024, which claims priority to Chinese Patent Application No. 202310653873.1, filed on Jun. 2, 2023, in the China National Intellectual Property Administration, with a name “Display panel, display device and manufacturing method of display panel”. The entire disclosure of the above applications is incorporated herein by reference.

### TECHNICAL FIELD

The present disclosure relates to the field of semiconductor technology, and in particular to a display panel, a display device and a manufacturing method of a display panel.

### BACKGROUND

With the rise of the concept of the metaverse, virtual reality (VR) technology headset products have attracted much attention as port devices. Currently, the display products with good effects on the market are usually micro organic light-emitting display devices (Micro OLED) products of 3000+PPI, but Micro OLED products have high cost, difficult process, and difficult to popularize.

### SUMMARY

The present disclosure provides a display panel, a display device and a manufacturing method of a display panel. The display panel is provided with a display area including a plurality of light-transmitting regions and a non-display area located at a periphery of the display area, the display panel includes:
a base substrate;
a first transistor, located in the display area on a side of the base substrate, and including a first active layer;
a first electrode, located on a side of the first active layer facing away from the base substrate;
a first insulating layer, located between the first active layer and the first electrode, and being in contact with the first electrode,
the first insulating layer is provided with a first through hole penetrating the first insulating layer, and an orthographic projection of the first through hole on the base substrate is located in an orthographic projection of the light-transmitting regions on the base substrate to make the first electrode be electrically connected with the first active layer through the first through hole.

In some embodiments, the display panel further includes:
a second insulating layer located between the first insulating layer and the first active layer, wherein the second insulating layer is provided with a second through hole;
a connecting electrode between the first electrode and the first active layer, wherein a part of the connecting electrode is located on a side of the first insulating layer facing away from the base substrate, and is in contact with the first electrode;
the first electrode is electrically connected with the first active layer through the connecting electrode at the second through hole and the first through hole.

In some embodiments, an orthographic projection of the second through hole on the base substrate is located in the orthographic projection of the light-transmitting regions on the base substrate.

In some embodiments, the display panel further includes:
a plurality of signal lines extending along a first direction;
the orthographic projection of the first through hole on the base substrate and an orthographic projection of the second through hole on the base substrate are located between an orthographic projection of a N^{th} signal line on the base substrate and an orthographic projection of a (N+1)^{th} signal line on the base substrate;
in a direction perpendicular to the first direction, the orthographic projection of the first through hole on the base substrate is on a side of the orthographic projection of the second through hole on the base substrate facing away from the N^{th} signal line, wherein N is a positive integer.

In some embodiments, the connecting electrode includes:
a first connecting sub-electrode located between the second insulating layer and the first insulating layer, and
a second connecting sub-electrode between the first electrode and the first insulating layer;
a part of the first connecting sub-electrode is located at a bottom of the second through hole and is in contact with the first active layer at the bottom of the second through hole; a part of the first connecting sub-electrode extends to a bottom of the first through hole on a side of the second insulating layer facing away from the base substrate, and is in contact with the second connecting sub-electrode at the bottom of the first through hole;
a part of the second connecting sub-electrode is located at the bottom of the first through hole and is in contact with the first connecting sub-electrode at the bottom of the first through hole; a part of the second connecting sub-electrode extends to a side of the first insulating layer facing away from the base substrate and is in contact with the first electrode.

In some embodiments, the display panel further includes:
a third insulating layer filled in the first through hole,
a segment difference between a surface of the third insulating layer facing away from the base substrate and a surface of the first insulating layer facing away from the base substrate is less than 0.2 μm.

In some embodiments, the orthographic projection of the first through hole on the base substrate covers the orthographic projection of the second through hole on the base substrate; one end of the connecting electrode is directly in lap-contact with the first active layer, and the other end of the connecting electrode is directly in lap-contact with the first electrode.

In some embodiments, the display panel further includes:
a third insulating layer filled in the second through hole and the first through hole,
a segment difference between a surface of the third insulating layer facing away from the base substrate, and the a surface of the first insulating layer facing away from the base substrate is less than 0.2 μm.

In some embodiments, a material of the first active layer includes a metal oxide doped with rare earth elements.

In some embodiments, an orthographic projection of the first electrode on the base substrate covers the orthographic projection of the first through hole on the base substrate and the orthographic projection of the second through hole on the base substrate.

In some embodiments, the first active layer includes a first active portion, and the first active portion is located in the light-transmitting regions; the first electrode is electrically connected with the first active part through the first through hole.

In some embodiments, the display panel of claim 11, further includes:
a first gate layer, and
a first source-drain layer;
wherein the first gate layer includes the signal lines, and the signal lines include gate lines; the first source-drain layer includes a plurality of data lines of which main bodies extend along a second direction;
the first active layer further includes a second active portion, and a third active portion connecting the first active portion with the second active portion; an orthographic projection of the second active portion on the base substrate partially overlaps with orthographic projections of the data lines on the base substrate;
the second insulating layer is further provided with a third through hole, and the data lines are electrically connected with the second active portion through the third through hole;
the display panel further includes a gate drive circuit located in the non-display area, and the gate drive circuit includes a first driving active layer, a first driving gate, and a first driving source-drain.

In some embodiments, the display panel further includes:
a gate structure located on a side of the first active layer facing away from the base substrate,
an orthographic projection of the gate structure on the base substrate covers an orthographic projection of at least part of the third active portion on the base substrate.

In some embodiments, the gate lines include gate portions; the third active portion includes an overlapping portion, wherein an orthographic projection of the overlapping portion on the base substrate overlaps with orthographic projections of the gate portions on the base substrate;
the orthographic projection of the gate structure on the base substrate at least covers the orthographic projection of the overlapping portion on the base substrate.

In some embodiments, the gate structure includes:
auxiliary gates arranged at a side of the gate portions facing the base substrate;
orthographic projections of the auxiliary gates on the base substrate cover the orthographic projections of the gate portions on the base substrate, and covers at least one of two sides of the gate portions in the second direction.

In some embodiments, the gate structure includes:
auxiliary gates arranged at a side of the gate portions facing away from the base substrate;
orthographic projections of the auxiliary gates on the base substrate covers the orthographic projections of the gate portions on the base substrate, and covers at least one of two sides of the gate portions in the second direction.

In some embodiments, the gate structure includes:
the gate portions, and
auxiliary gates located at two sides of the gate portions in the second direction,
the orthographic projections of the gate portions on the base substrate do not overlap with the orthographic projections of the auxiliary gates on the base substrate.

In some embodiments, a maximum spacing of orthographic projections of the auxiliary gates on the base substrate in the second direction is greater than or equal to a maximum spacing of orthographic projections of the gate portions on the base substrate in the second direction.

In some embodiments, the gate lines extend from a first end to a second end along the first direction; the first active layer includes a first active group and a second active group alternately arranged in the second direction;
the first active group includes a plurality of first active patterns extending along a third direction and arranged sequentially along the first direction, the first active patterns include the first active portion, the second active portion and the third active portion; an angle between the first active patterns and the gate lines toward the first end is an acute angle;
the second active group includes a plurality of second active patterns extending along a fourth direction and arranged sequentially along the first direction, the second active patterns include the first active portion, the second active portion and the third active portion; an angle between the second active patterns and the gate lines toward the first end is an obtuse angle.

In some embodiments, the gate lines extend from a first end to a second end along the first direction;
the first active portion, the second active portion, and the third active portion all extend along the second direction, and an angle formed by each of the first active portion, the second active portion, and the third active portion with the gate lines toward the first end is a right angle.

In some embodiments, the gate lines extend from a first end to a second end along the first direction;
the first active portion and the second active portion extend along the second direction, and an extension line of the first active portion does not coincide with an extension line of the third active portion; an angle between at least a part of the third active portion and the gate lines toward the first end is an acute angle.

In some embodiments, the first active portion, the second active portion, and the third active portion all extend along the first direction, and gaps are arranged between an orthographic projection of the first active layer on the base substrate and orthographic projections of the gate lines on the base substrate;
the third active portion is located in the light-transmitting regions;
the gate structure includes auxiliary gates located at a side of the first active layer facing away from the base substrate, the auxiliary gates extend along the second direction, and orthographic projections of the auxiliary gates on the substrate cover an orthographic projection of the third active portion on the base substrate, and cover orthographic projections of a part of the gate lines on the base substrate.

In some embodiments, the first gate layer is located on a side of the first active layer facing the base substrate; the gate lines further include gate-line branches extending along the second direction; the orthographic projections of the auxiliary gates on the base substrate cover orthographic projections of the gate-line branches on the base substrate.

In some embodiments, a material of the auxiliary gates include indium tin oxide, indium-doped zinc oxide, fluorine-doped tin oxide, aluminum-doped zinc oxide, or indium-doped cadmium oxide.

In some embodiments, the data lines include:
a first data portion and a second data portion, which extend along the second direction and are alternately arranged along the second direction, and
a third data portion connecting the first data portion with the second data portion and extending along the first direction,
an extension line of the first data portion does not coincide with an extension line of the second data portion.

In some embodiments, the display panel further includes:
common electrodes located on a side of the first electrode facing away from the base substrate;
wherein the common electrodes include:
first common electrode portions extending along the first direction, and
second common electrode portions extending along the second direction;
orthographic projection of the first common electrode portions on the base substrate cover orthographic projections of the gate lines on the base substrate, and orthographic projections of the second common electrodes on the base substrate cover the orthographic projections of the data lines on the base substrate;
the orthographic projection of the first through hole on the base substrate is located in an orthographic projection of a region enclosed by the first common electrodes and the second common electrodes intersecting with each other on the base substrate.

In some embodiments, the display panel further includes:
a first shading layer located on a side of the common electrodes facing away from the first electrode and being in direct contact with the common electrodes, and
a spacer located on a side of the first shading layer facing away from the first electrode layer;
the orthographic projections of the common electrodes on the base substrate, cover an orthographic projection of the first shading layer on the base substrate, and a line width of the first shading layer is smaller than a line width of the common electrodes; the orthographic projection of the first shading layer on the base substrate covers an orthographic projection of the spacer on the base substrate, and a line width of the spacer is smaller than the line width of the first shading layer.

In some embodiments, the orthographic projection of the first shading layer on the base substrate covers the orthographic projections of the data lines on the base substrate and covers the orthographic projections of the gate lines on the base substrate;
the orthographic projection of the spacer on the base substrate covers the orthographic projections of the data lines on the base substrate, and covers the orthographic projections of the gate lines the base substrate.

In some embodiments, a material of the first shading layer includes blackened metal; a material of the spacer includes molybdenum or aluminum.

In some embodiments, the first driving active layer and the first active layer are on a same layer; the first driving gate and the first gate layer are on a same layer; the first driving source-drain and the first source-drain layer are on a same layer.

In some embodiments, the display panel further includes: a second gate layer located between the base substrate and the first active layer; the second gate layer includes: a first gate in the display area, and a second driving gate in the non-display area; the orthographic projections of the gate lines on the base substrate cover an orthographic projection of the first gate on the base substrate; an orthographic projection of the second driving gate on the base substrate covers an orthographic projection of the first driving gate on the base substrate.

In some embodiments, the display panel further includes:
a second gate located in the display area and between the base substrate and the first active layer;
the first driving source-drain and the second gate are on a same layer and of a same material; a material of the first driving active layer includes polysilicon.

In some embodiments, the first driving source-drain and the first source-drain layer are on a same layer; a material of the first driving active layer includes polysilicon.

Some embodiments provide a display device, including the display panel of embodiments of the present disclosure.

Some embodiments further provide a manufacturing method of the display panel of embodiments of the present disclosure, including:
providing the base substrate;
forming the first active layer and the first insulating layer on a side of the base substrate, and forming the first through hole in the first insulating layer;
forming the first electrode on the side of the first insulating layer facing away from the first active layer to make the first electrode electrically connected with the first active layer through the first through hole.

In some embodiments, the forming the first active layer and the first insulating layer on the side of the base substrate, includes:
forming a second insulating layer on the side of the first active layer facing away from the base substrate, and forming a second through hole exposed in the second insulating layer;
forming a first connecting sub-electrode in a region where the second through hole is located;
forming the first insulating layer on a side of the second insulating layer facing away from the first active layer, and forming the first through hole in the first insulating layer;
forming a second connecting sub-electrode in a region where the first through hole is located;
filling a region on a side of the second connecting sub-electrode facing away from the first connecting sub-electrode and located in the first through hole.

In some embodiments, the forming the first active layer and the first insulating layer on a side of the base substrate, includes:
forming a second insulating layer on a side of the first active layer facing away from the base substrate;
forming the first insulating layer on a side of the second insulating layer facing away from the first active layer;
forming, through one patterning process, the first through hole that penetrates the first insulating layer and a second through hole that penetrates the second insulating layer and exposes a part of the first active layer;
forming a connecting electrode in a region where the second through hole and the first through hole are located;
filling a region on a side of the connecting electrode facing away from the first active layer and located in the second through hole and the first through hole with a third insulating layer.

In some embodiments, after the forming the first electrode on a side of the first insulating layer facing away from the first active layer, the manufacturing method further includes:
forming a first shading film and a spacer film successively on a side of the first electrode facing away from the base substrate;
forming a shading layer and a spacer by patterning the first shading film and the spacer film through one masking process.

### BRIEF DESCRIPTION OF FIGURES

FIG. 1A is the first top view of the display panel provided by an embodiment of the present disclosure;

FIG. 1B is a schematic diagram of the single layer of the first active layer in FIG. 1A;

FIG. 1C is a schematic diagram of a single layer of the grid-line layer in FIG. 1A;

FIG. 1D is a schematic diagram of a single layer of the data line in FIG. 1A;

FIG. 1E is a schematic diagram of the first connecting sub-electrode in FIG. 1A;

FIG. 1F is a schematic diagram of the outer contour of the second connecting sub- electrode and the first electrode in FIG. 1A;

FIG. 2A is the first schematic diagram of the cross-section along the dashed line E1F1 in FIG. 1A;

FIG. 2B is a schematic diagram of the cross-section of two through holes provided by an embodiment of the present disclosure;

FIG. 2C is a schematic diagram of another two through holes provided by an embodiment of the present disclosure;

FIG. 3 is the second top view of the display panel provided by an embodiment of the present disclosure;

FIG. 4 is a schematic view of the cross-section along the dashed line E2F2 in FIG. 3;

FIG. 5 is the first cross-sectional view of the display panel provided by an embodiment of the present disclosure;

FIG. 6 is the second cross-sectional view of the display panel provided by an embodiment of the present disclosure;

FIG. 7 is the third cross-sectional view of the display panel provided by an embodiment of the present disclosure;

FIG. 8 is the fourth cross-sectional view of the display panel provided by an embodiment of the present disclosure;

FIG. 9 is the third top view of the display panel provided by an embodiment of the present disclosure;

FIG. 10 is the fourth top view of the display panel provided by an embodiment of the present disclosure;

FIG. 11 is the fifth top view of the display panel provided by an embodiment of the present disclosure;

FIG. 12A is a schematic diagram of the cross-section along the dashed line E6F6 in FIG. 12B;

FIG. 12B is the sixth top view of the display panel provided by an embodiment of the present disclosure;

FIG. 13A is a schematic diagram of the cross-section along the dashed line E7F7 in FIG. 13B;

FIG. 13B is the seventh top view of the display panel provided for the embodiment of the present disclosure;

FIG. 14A is the eighth top view of the display panel provided by an embodiment of the present disclosure;

FIG. 14B is a schematic diagram of a single layer of a common electrode in FIG. 14A;

FIG. 15 is the fifth cross-sectional view of the display panel provided by an embodiment of the present disclosure;

FIG. 16 is the sixth cross-sectional view of the display panel provided by an embodiment of the present disclosure;

FIG. 17 is the seventh cross-sectional view of the display panel provided by an embodiment of the present disclosure;

FIG. 18 is the eighth cross-sectional view of the display panel provided by an embodiment of the present disclosure;

FIG. 19 is the ninth cross-sectional view of the display panel provided by an embodiment of the present disclosure;

FIG. 20 is the tenth cross-sectional view of the display panel provided by an embodiment of the present disclosure;

FIG. 21 is the first flow chart of the manufacturing process of the display panel provided by an embodiment of the present disclosure;

FIG. 22 is the second flow chart of the manufacturing process of the display panel provided by an embodiment of the present disclosure.

### DETAILED DESCRIPTION

The embodiments of the present disclosure are described in detail below in conjunction with the accompanying drawings. Implementation can be done in a number of different forms. A person of ordinary skill in the art to which he belongs can easily understand the fact that the means and contents may be transformed into one or more forms without departing from the purpose of the present disclosure and its scope. Therefore, this disclosure should not be construed as confined to the contents described in the following embodiments. Without conflict, the embodiments in the present disclosure and the features in the embodiments may be arbitrarily combined with each other.

In the drawings, the size, thickness or area of the layers of one or more constituent elements are sometimes exaggerated for clarity. Therefore, one of the methods of the present disclosure is not necessarily limited to that size, and the shape and size of the parts in the drawings do not reflect the true proportions. In addition, the drawings illustrate ideal examples, and one of the ways in which this disclosure is made is not limited to the shapes, values, etc., shown in the drawings.

Ordinal numerals such as “first”, “second” and “third” in this specification are set to avoid confusion of constituent elements, and are not intended to be quantitatively qualified. The word “multiple”, “a plurality of” in the present disclosure may include two or more quantities.

In this description, for convenience, the use of words and phrases such as “middle”, “top”, “bottom”, “front”, “rear”, “vertical”, “horizontal”, “top”, “bottom”, “inside”, “outside”, etc., indicating orientation or positional relationship, to illustrate the positional relationship of the constituent elements with reference to the accompanying drawing, is only for the convenience of describing this description and simplifying the description, and does not indicate or imply that the device or element referred to must have a specific orientation, be constructed and operated in a specific orientation, and therefore cannot be construed as a limitation of the present disclosure. The positional relationships of the constituent elements change appropriately according to the direction in which the constituent elements are described. Therefore, it is not limited to the words and phrases stated in the manual, and can be replaced appropriately according to the situation.

In this specification, unless otherwise expressly specified or limited, the terms “mounted”, “connected” and “connecting” shall be construed broadly. For example, it can be a fixed connection, or a detachable connection, or a one-piece connection. It can be mechanically connected, or electrically connected. It can be directly connected, indirectly connected by middleware, or connected within two components. For those of ordinary skill in the art, the meaning of the above terms in the present disclosure may be understood as appropriate.

For the purposes of this manual, “electrically connected” includes a situation in which the constituent elements are connected together by elements that have some electrical effect. There are no special restrictions on “elements with a certain electrical function” as long as they can transmit electrical signals between the constituent elements of the connection. Examples of “components with some electrical function” include not only electrodes and wiring, but also switching elements such as transistors, resistors, inductors, capacitors, and other components with one or more functions.

In this specification, a transistor is a component that includes at least three terminals: the gate electrode (gate), the drain electrode, and the source electrode. The transistor has a channel region between the drain electrode (drain terminal, drain region, or drain) and the source electrode (source terminal, source region, or source), and current can flow through the drain electrode, the channel region, and the source electrode. In the present disclosure, a channel region refers to a region through which the current flows primarily.

In addition, the gate of a transistor can be called a control terminal. In the case of the use of transistors of opposite polarity or changes in the direction of the current during circuit operation, the functions of the “source electrode” and “drain electrode” may be reversed. Therefore, in this specification, the “source electrode” and “drain electrode” can be interchanged.

In this specification, “parallel” refers to a state in which two straight lines form an angle grater than or equal to −10° and less than or equal to 10°, so it can include a state in which the angle is more than or equal to −5° and less than or equal to 5°. In addition, “perpendicular” refers to a state in which two straight lines form an angle greater than or equal to 80° and less than or equal to 100°, so it can include an angle greater than or equal to 85° or less than or equal to 95°.

In this specification, triangles, rectangles, trapezoids, pentagons or hexagons are not strictly sense, but can be approximate triangles, rectangles, trapezoids, pentagons or hexagons, etc., and there can be some small deformations caused by tolerances, and there can be guide angles, arc edges and deformations.

In this specification, “film” and “layer” can be interchangeable. For example, sometimes “conductive layer” can be replaced with “conductive film”. In the same way, it is sometimes possible to replace “insulating film” with “insulating layer”.

The terms “about” and “approximately” in this specification refer to the situation that the boundaries are not strictly defined, and the process and measurement errors are allowed. In this specification, “roughly the same” can refer to cases where the values differ by less than 10%.

At present, the best choice scheme for ultra-high PPI (Pixel Per Inch) is liquid crystal display (LCD) technology, because in the LCD display structure, the pixel area circuit has only one switching transistor (TFT), which is very conducive to achieving high PPI, but the LCD transmittance is low, and it is necessary to develop a backplane process scheme with high aperture ratio, especially when the PPI reaches more than 2000, various line widths, line spacing and through hole size are all at the limit of display manufacturing equipment, and the area of the opening area is drastically compressed, thus requiring a new backplane structure to improve the backlight efficiency.

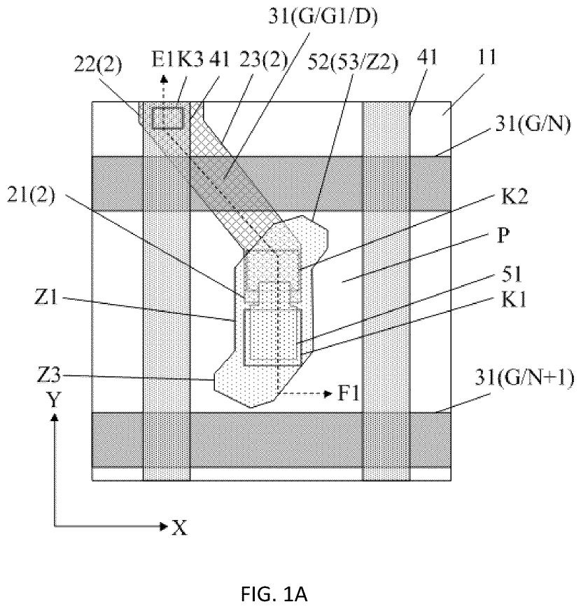

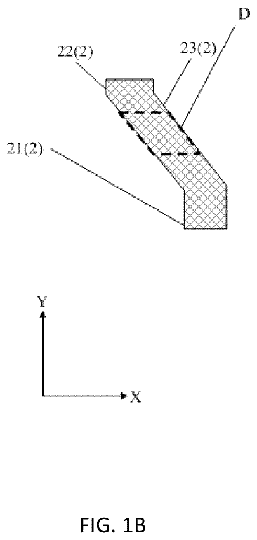

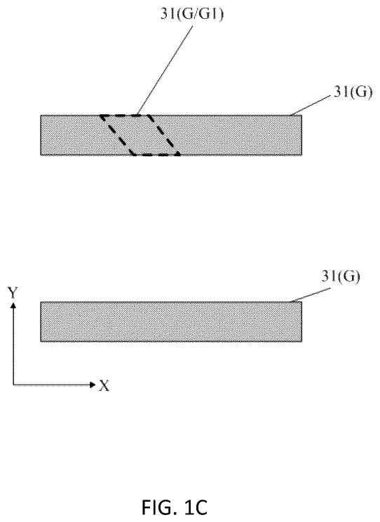

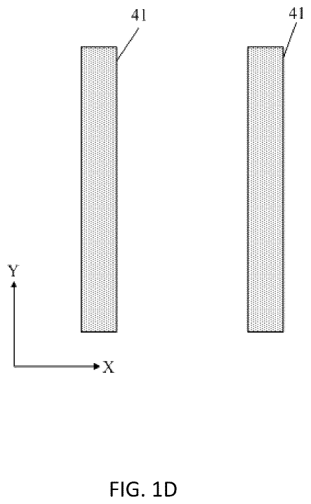

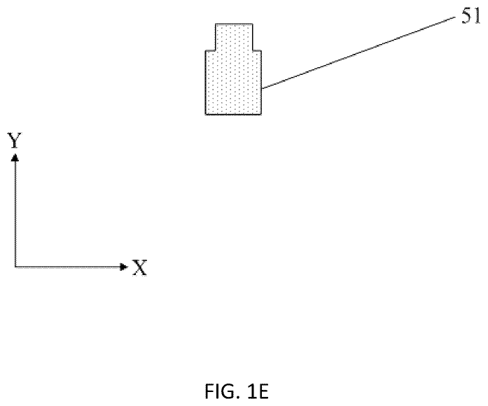

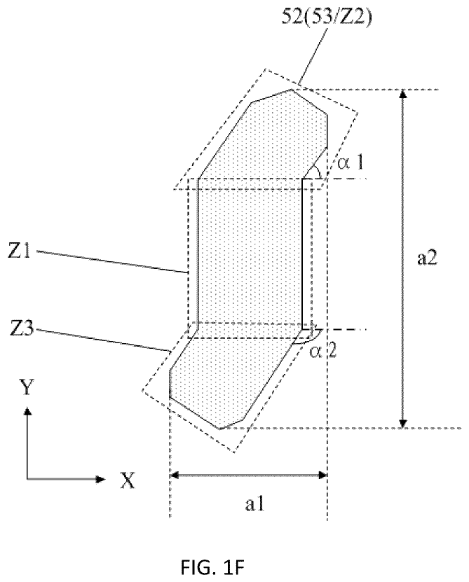

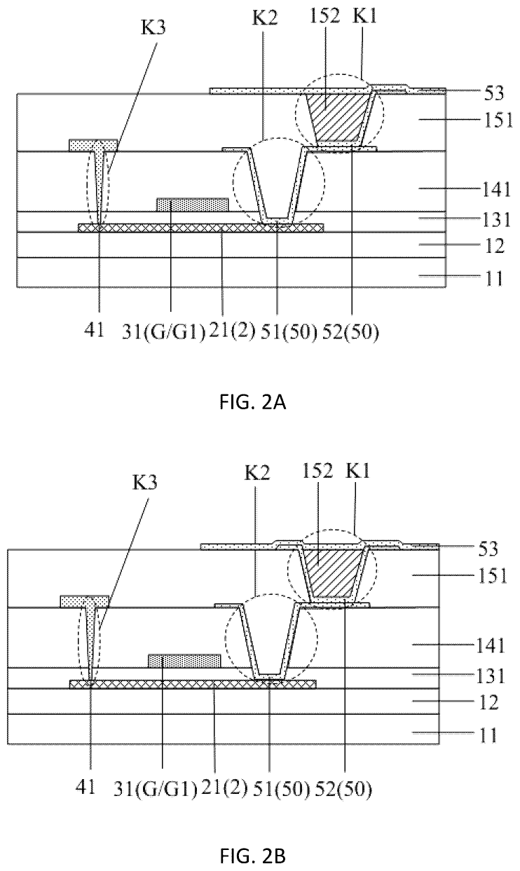

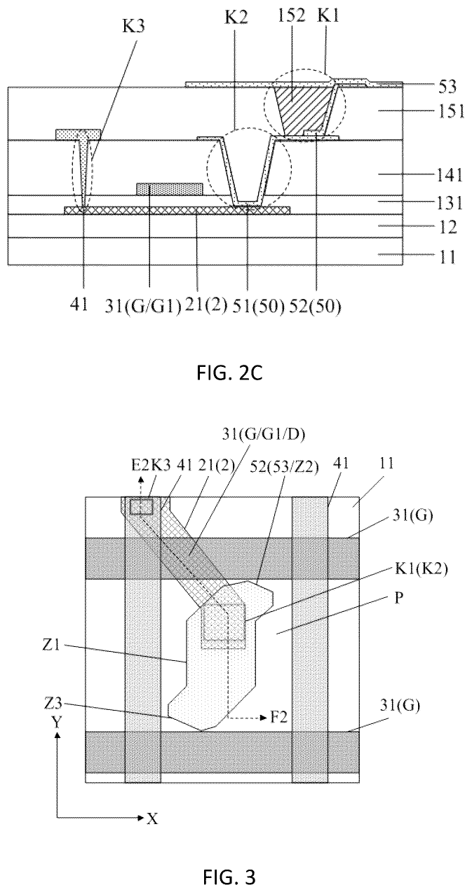

In view of this, some embodiments of the present disclosure provide a display panel, as shown in FIG. 1A to FIG. 1F, FIG. 2A, FIG. 2B and FIG. 2C. FIG. 1B is a schematic diagram of the single layer of the first active layer in FIG. 1A. FIG. 1C is a schematic diagram of a single layer of the gate line in FIG. 1A. FIG. 1D is a schematic diagram of the data line in FIG. 1A. FIG. 1E is a schematic diagram of the first connecting sub-electrode in FIG. 1A. FIG. 1F is a schematic diagram of the outer contour of the second connecting sub-electrode and the first electrode in FIG. 1A. FIG. 2A is the first schematic diagram of the cross-section along the dashed line E1F1 in FIG. 1A. FIG. 2B is a cross-sectional view of two through holes provided in the embodiment of the present disclosure. FIG. 2C is a cross-sectional view of another two through holes provided in the embodiment of the present disclosure. The display panel includes a display area and a non-display area located at the periphery of the display area. The display area includes a plurality of light-transmitting areas P, and the display panel includes:
a base substrate 11;
a first transistor (not shown in the figure) located in the display area on a side of the base substrate 11, and first transistor including a first active layer 2;
a first electrode 53 located on a side of the first active layer 2 facing away from the base substrate 11, specifically, the first electrode 53 may be a pixel electrode;
a first insulating layer 151 located between the first active layer 2 and the first electrode 53 and in contact with the first electrode 53, the first insulating layer 151 including a first through hole K1 penetrating through the first insulating layer 151. The orthographic projection of the first through hole K1 on the base substrate 11 is located in the orthographic projection of the light-transmitting region P on the base substrate 11, specifically, the area of the orthographic projection of the light-transmitting region P on the base substrate 11 is greater than the area of the orthographic projection of the first through hole K1 on the base substrate 11. The orthographic projection of the light-transmitting region P on the base substrate 11 covers the orthographic projection of the first through hole K1 on the base substrate 11, so that the first electrode 53 is electrically connected with the first active layer 2 through the first through hole K1. Specifically, the first insulating layer 151 may be the first planarization layer.

In the embodiment of the disclosure, the first through hole K1 electrically connecting the first electrode 51 and the first active layer 2 is arranged in the light-transmitting region P. With respect to the related art, the first through hole K 1 electrically connecting the first electrode 51 with the first active layer 2 is arranged at the position of the trace in the non-transparent area, a part of the first electrode is electrically connected with the first active layer, and the other part of the first electrode is used for display, and the area of the conduction connection is located in a region other than the light-transmitting region P and cannot be used for display, so that the effective area of the first electrode 53 is smaller. In the embodiment of the present disclosure, the first through hole K1 electrically connecting the first electrode 53 with the first active layer 2 is located in the light-transmitting region P, and the first electrode 53 is electrically connected with the first active layer 2 while being used for display, the effective area of the first electrode 53 is increased, the liquid crystal efficiency (the deflection ability of the liquid crystal to the linearly polarized light) is improved, and the light transmittance of the display panel is improved.

In some embodiments, the light-transmitting region P can be understood as a region in the display panel where the sub-pixels are used for display. Specifically, the display panel can include a black matrix, and the black matrix can include a black matrix opening. The orthographic projection of the light-transmitting region P on base substrate 11 can coincide with the orthographic projection of the black matrix opening on base substrate 11.

In some embodiments, the display panel may include a shading structure (not shown in the figure). The orthographic projection of the shading structure on the base substrate 1 does not overlap with the orthographic projection of the light-transmitting region P on the base substrate 1. Specifically, the display panel may include an array substrate and a color film substrate that are arranged opposite each other. The shading structure may include a black matrix arranged on the array substrate and/or the color film substrate. The shading structure may also include a shading layer located on the array substrate, and specifically, the shading layer may be a shading metal layer.

In a possible embodiment, as shown in FIG. 1A to FIG. 1F, FIG. 2A, FIG. 2B and FIG. 2C, the display panel further includes: a second insulating layer 141 arranged between the first insulating layer 151 and the first active layer 2. The second insulating layer 141 includes a second through hole K2. The display panel further includes: a connecting electrode 50 arranged between the first electrode 53 and the first active layer 2. The connecting electrode 50 is located on a side of the first insulating layer 151 facing away from the base substrate 1 and is in contact with the first electrode 53. The first electrode 53 is electrically connected with the first active layer 2 at the second through hole K2 and the first through hole K1 through the connecting electrode 50. Specifically, the second insulating layer 141 may be the first interlayer dielectric layer.

In one possible embodiment, as shown in FIG. 1A to FIG. 1F, FIG. 2A, FIG. 2B and FIG. 2C, the orthographic projection of the second through hole K2 on the base substrate 11 is located in the orthographic projection of the light-transmitting region P on the base substrate 11. Specifically, the area of the orthographic projection of the light-transmitting region P on the base substrate 11 is greater than the area of the orthographic projection of the second through hole K2 on the base substrate 11. The orthographic projection of the light-transmitting region P on the base substrate 11 covers the orthographic projection of the second through hole K2 on the base substrate 11. In one possible embodiment, the second through hole K2 may also be not located in the light-transmitting region P. Alternatively, a part of the second through hole K2 is located in the light-transmitting region P and the other part of the second through hole K2 is at a location other than the light-transmitting region P.

In one possible embodiment, as shown in FIG. 1A to FIG. 1F, FIG. 2A, FIG. 2B, and FIG. 2C, the orthographic projection center of the first through hole K1 on base substrate 11 does not coincide with the orthographic projection center of the second through hole K2 on base substrate 11. Specifically, the display panel includes a first gate layer. The first gate layer includes a plurality of gate lines 31 extending in the first direction. The orthographic projection of the first through hole K1 and the orthographic projection of the second through hole K2 on the base substrate 11 are located between the orthographic projection of the Nth gate line 31 and the orthographic projection of the (N+1)th gate line 31 on the base substrate. In a direction perpendicular to the first direction X, the orthographic projection of the first through hole K1 on the base substrate 11 is located on a side of the orthographic projection of the second through hole K2 on the base substrate 11 facing away from the Nth gate line 31, N is a positive integer.

It should be noted that the Nth gate line and the (N+1)th gate line are the adjacent two gate lines sequentially loading a scanning signal on the display panel. The (N+1)th gate line is a gate line behind the Nth gate line in the scanning direction, that is, when the display panel loads the scanning signal, the scanning signal is loaded to the Nth gate line first, and then the scanning signal is loaded to the (N+1)th gate line, that is, the Nth gate line loads the scanning signal in prior to the (N+1)th gate line.

In one possible embodiment, as shown in FIG. 1A to FIG. 1F, FIG. 2A, FIG. 2B and FIG. 2C, the orthographic projection of the first through hole K1 on the base substrate 11 and the orthographic projection of the second through hole K2 on base the substrate 11 do not overlap with each other. Specifically, the connecting electrode 50 includes a first connecting sub-electrode 51 located between the second insulating layer 141 and the first insulating layer 151, and a second connecting sub-electrode 52 located between the first electrode 53 and the first insulating layer 151. The first connecting sub-electrode 51 is partially located at the bottom of the second through hole K2 and is in contact with the first active layer 2 at the bottom of the second through hole K2, and partially extends outward the bottom of the first through hole K1 on a side of the second insulating layer 141 facing away from the base substrate 11, and is in contact with the second lap sub-electrode 52 at the bottom of the first through hole K1. The second connecting sub-electrode 52 is partially located at the bottom of the first through hole K1 and is in contact with the first connecting sub-electrode 51 at the bottom of the first through hole K1, and partially extends outward a side of the first insulating layer 151 facing away from the base substrate 1 and is in contact with the first electrode 53. In the embodiment of the disclosure, the display panel includes a first through hole K1 and a second through hole K2, that is, the first through hole K1 is made in the first insulating layer 151 and a second through hole K2 is made in the second insulating layer 141 respectively. The first electrode 53 is electrically connected with the first active layer 2 through a two-step etching process. In comparison to the first electrode 53 being electrically connected with the first active layer 2 through one through hole, of which the etching difficulty is greater, the first electrode 53 is electrically connected with the first active layer 2 through two through holes in the embodiment of the disclosure, which can achieved by an easier process.

Specifically, as shown in FIG. 1A to FIG. 1F, FIG. 2A, FIG. 2B and FIG. 2C, the first connecting sub-electrode 51 is partially located at the bottom of the second through hole K2 to achieve a contact lap with the first active layer 2, partially covers the side wall of the second through hole K2 and climbs to extend outwardly to the upper portion of the second insulating layer 141, and extends to the bottom of the first through hole K1, so as to realize the electrical connection with the second connecting sub-electrode 52. Specifically, the orthographic projection of the first connecting sub-electrode 51 on the base substrate 11 may partially cover the orthographic projection of the second through hole K2 on the base substrate 11, or may cover the entire orthographic projection of the second through hole K2 on the base substrate 11.

The second connecting sub-electrode 52 is partially located at the bottom of the first through hole K1, and is in contact with the first connecting sub-electrode 51. Te second connecting sub-electrode 52 also partially covers the side wall of the first through hole K1 and climbs to extend outward to the periphery of the first through hole K1 and covers the upper portion of the first insulating layer 151, so as to realize the contact lap with the first electrode 53. Specifically, the orthographic projection of the second connecting sub-electrode 52 on the base substrate 11 may partially cover the orthographic projection of the first through hole K1 on the base substrate 11, or may cover the entire orthographic projection of the first through hole K1 on the base substrate 11.

The specific pattern of the second connecting sub-electrode 52 can be designed as required, and the orthographic projection the second connecting sub-electrode 52 on the base substrate 11 can be a triangle, a quadrilateral, a pentagon, a hexagon, a circle, an oval, or other irregular shape. The specific pattern of the second connecting sub-electrode 52 needs to be satisfied: on the one hand, the contact lap can be realized between the second connecting sub-electrode 52 and the first electrode 53, and on the other hand, after being stacked with the first electrode 53, the overall outer contour of the second connecting sub-electrode 52 and the first electrode 53 covers the orthographic projections of the first through hole K1 and the second through hole K2 on the base substrate 11. Specifically, as shown in FIG. 1F, the overall outer contour shape of the second connecting sub-electrode 52 and the first electrode 53 after being stacked can be strip-shaped. The maximum length a1 of the overall outer contour shape in the first direction X can be smaller than the maximum length a2 of the overall outer contour shape in the second direction Y. The maximum length a1 of the overall outer contour shape in the first direction X can be smaller than the length of the light-transmitting region P in the first direction X, or the maximum length a1 of the overall outer contour shape in the first direction X can be equal to the length of the light-transmitting region P in the first direction X. The maximum length a2 of the overall outer contour shape in the second direction Y can be greater than the length of the light-transmitting region P in the second direction Y. Alternatively, the maximum length a2 of the overall outer contour shape in the second direction Y can be equal to the length of the light-transmitting region P in the second direction Y. Alternatively, the maximum length a2 of the overall outer contour shape in the second direction Y can be smaller than the length of the light-transmitting region P in the second direction Y.

In one possible embodiment, at the first through hole K1, the second connecting sub- electrode 52 may only overlap a side of the first insulating layer 151 facing away from the base substrate 1 at the first through hole K1, as shown in FIG. 2A. The second connecting sub-electrode 52 may also overlap the entire outer edge of the first insulating layer 151 facing away from the base substrate 1 at the first through hole K1, as shown in FIG. 2B. In one possible embodiment, the second connecting sub-electrode 52 is at the bottom of the first through hole K1, and cover the entire bottom of the first through hole K1, as shown in FIG. 2A. The second connecting sub-electrode 52 is at the bottom of the first through hole K1, and covers a part of the bottom of the first through hole K1, as shown in FIG. 2C.

Specifically, as shown in FIG. 1F, the overall outer contour shape of the second connecting sub-electrode 52 and the first electrode 53 after being stacked, may include a first main body portion Z1, and a second extension portion Z2 extending from one end of the first main body portion Z1, and a third extension portion Z3 extending from the other end of the first main body portion Z1. The extension direction of the second extension portion Z2 can be different from the extension direction of the first main body portion Z1, and the extension direction of the third extension portion Z3 can be different from the extension direction of the first main body portion Z1. The first main body portion Z1 can extend along the second direction Y. The first angle α1 formed by the extension direction of the second extension portion Z2 and the first direction X can be 15° to 75°, such as 45°. The second angle α2 formed by the extension direction of the third extension portion Z3 and the first direction X can be −115° to −165°, such as −135°. The orthographic projection of the second extension portion Z2 on the base substrate 11 cannot overlap with the orthographic projection of the gate line 31 on a side of the light-transmitting region P on the base substrate 11. Alternatively, the orthographic projection of the second extension portion Z2 on base the substrate 11 can partially overlap with the orthographic portion of the gate line 31 on the side of the light-transmitting region P on the base substrate 11. The orthographic projection of the third extension portion Z3 on the base substrate 11 cannot overlap with the orthographic projection of the gate line 31 on the other side of the light-transmitting region P on the base substrate 11, and the orthographic projection of the third extension portion Z3 on the base substrate 11 can partially overlap with the orthographic projection of the gate line 31 on the other side of the light-transmitting region P on the base substrate 11. At least part of the first main body portion Z1 is exposed to the light-transmitting region P.

In one possible embodiment, as shown in FIG. 1A to FIG. 1F, FIG. 2A, FIG. 2B and FIG. 2C, the display panel further includes a third insulating layer 152 filled in the first through hole K1. The segment difference between a surface of the third insulating layer 151 facing away from the base substrate 11 and a surface of the first insulating layer 151 facing away from the base substrate 11 is less than 0.2 μm. Specifically, the third insulating layer 152 may be the second planarization layer. In the embodiment of the disclosure, the display panel further includes a third insulating layer 152 filled in the first through hole K1. The segment difference around the first through hole K1 can be planarized, and the segment difference between the surface of the third insulating layer 152 facing away from the base substrate 11 and the surface of the first insulating layer 151 facing away from the base substrate 11 is less than 0.2 μm, so as to avoid the abnormal liquid crystal orientation during the box matching process is carried out, if the segment difference is more than 0.2 μm, and avoid the light leakage problem if the segment difference around the first through hole K1 is too large.

Specifically, the first insulating layer 151 is the first planarization layer, because the first insulating layer is usually thicker, when the through holes are arranged, light leakage can occur, and in the conventional design, the through holes are arranged at the position where the shading metal wiring is located, so as to shield the light leakage. In the embodiment of the present disclosure, the first through hole K1 of the first insulating layer 151 is located in the light-transmitting region P, so that the effective area of the first electrode 53 can be increased, the liquid crystal efficiency can be improved, and the third insulating layer 152 is filled in the first through hole K1 to planarized the segment difference around the first through hole K1 so as to ensure that there is no light leakage problem caused by the segment difference.

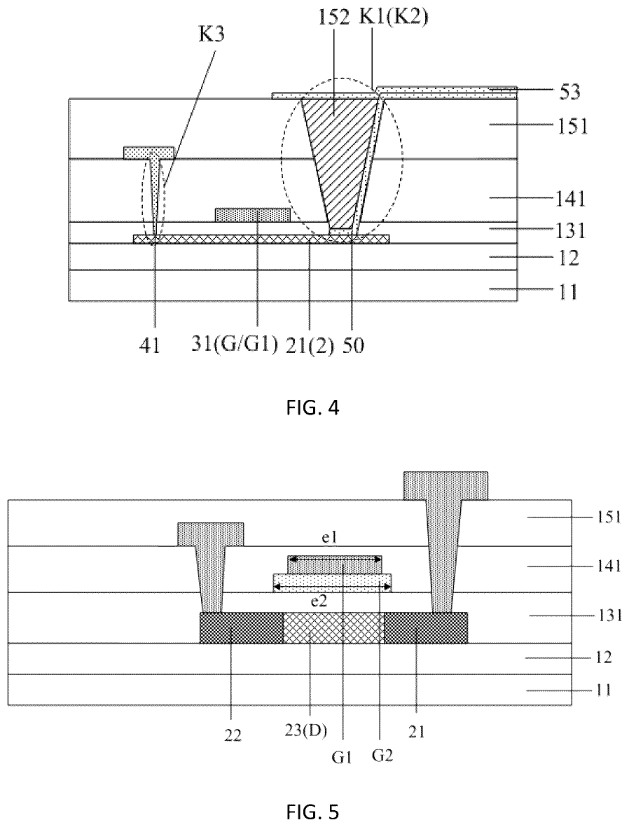

In one possible embodiment, as shown in FIG. 3 and FIG. 4, FIG. 4 is a schematic diagram of the cross-section along the dashed line E2F2 in of FIG. 3. The orthographic projection of the first through hole K1 on the base substrate 11 covers the orthographic projection of the second through hole K2 on base the substrate 11. One end of the connecting electrode 50 is in direct contact with the first active layer 2, and the other end of the connecting electrode 50 is in direct contact with the first electrode 53. Specifically, the second through hole K2 and the first through hole K1 can be formed by one-step etching. In the embodiment of the disclosure, the orthographic projection of the first through hole K1 on the base substrate 11 covers the orthographic projection of the second through hole K2 on the base substrate 11. In the specific embodiment, the first insulating layer 151 and the second insulating layer 141 can be formed by one-step etching, which can reduce one through hole in the light-transmitting region P, and simultaneously save two masking processes when patterning the second insulating layer 14 and the first connecting sub-electrode 51.

In one possible embodiment, as shown in FIG. 3 and FIG. 4, the display panel further includes a third insulating layer 152 filled in the second through hole K2 and the first through hole K1. The segment difference between a surface of the third insulating layer 152 facing away from the base substrate 11 and a surface of the first insulating layer 151 facing away from the base substrate 11 is less than 0.2 μm. In the embodiment of the disclosure, the display panel further includes a third insulating layer 152 filled in the second through hole K2 and the first through hole K1. The segment difference around the first through hole K1 and the second through hole K2 can be planarized by the third insulating layer 152. The segment difference between a surface of the third insulating layer 152 facing away from the base substrate 11 and a surface of the first insulating layer 151 facing away from the base substrate 11 is less than 0.2 μm, which can avoid that if the segment difference is more than 0.2 μm, the liquid crystal orientation will be abnormal during the box matching process, and avoid the light leakage problem due to the excessive segment difference around the first through hole K1.

In one possible embodiment, the material of the first active layer 2 includes a metal oxide doped with rare earth elements. Specifically, the material of the first active layer 2 is a metal oxide semiconductor material. The metal oxide semiconductor material may include at least one of indium gallium zinc oxide (IGZO), indium gallium oxide (IGO), indium gallium zinc tin oxide (IGZTO), indium zinc oxide (IZO), or rare earth element doped metal oxide (RE-OS). The rare earth element doped metal oxide may include lanthanide doped metal oxide (Ln-OS). The crystalline state of the material of the active layer can be amorphous, partially crystalline or polycrystalline. In the embodiment of the present disclosure, the material of the first active layer 2 is a metal oxide doped with rare earth elements, and the first active layer 2 can have stable performance even if it is exposed to light, and then the shading layer does not need to be arranged in the light-transmitting region P, and the aperture ratio of the display panel can be further improved.

In one possible embodiment, as shown in FIG. 1A to FIG. 4, the orthographic projection of the first electrode 53 on the base substrate 11, covers the orthographic projection of the first through hole K1 and the orthographic projection of the second through hole K2 on the base substrate 11. Since a second connecting sub-electrode 52 is distributed in the first through hole K1 and a first connecting sub-electrode 51 is distributed in the second through hole K2, an electric field can be formed by an electrode layer (such as a common electrode layer) above the first electrode 53 and the connecting electrodes in the through holes, which may then interfere with the normal electric field formed by the first electrode 53 and the common electrode layer, thereby affecting the normal deflection loaded on the liquid crystal. In the embodiment of the present disclosure, the electric field in the through holes can be shielded through the first electrode 53 covering the orthographic projection of the first through hole 53 and the orthographic projection of the second through hole K2 on the base substrate 11, so as to achieve a stable electric field.

In one possible embodiment, as shown in FIG. 1A to FIG. 4, the first active layer 2 includes a first active portion 21. The first active portion 21 is located in the light-transmitting region P. The first electrode 53 is electrically connected with the first active portion 21 through the first through hole K 1. In the embodiment of the disclosure, the first active layer 2 includes a first active portion 21 located in the light-transmitting region P, so as to realize an electrically conductive connection between the first active layer 2 and the first electrode 53 in the light-transmitting region P.

In a possible embodiment, as shown in FIG. 1A to FIG. 4, the display panel further includes a first source-drain layer. The first source-drain layer includes a plurality of data lines 41 extending along the second direction Y. The first active layer 2 further includes a second active portion 22, and a third active portion 23 connecting the first active portion 21 and the second active portion 22. The orthographic projection of the second active portion 22 on the base substrate 11 overlaps partially with the orthographic projection of the data lines 41 on the base substrate 11. The second insulating layer 141 further includes a third through hole K3 exposing the second active portion 22. The data lines 41 are electrically connected with the second active portion 22 through the third through hole K3. In the embodiment of the disclosure, the first active layer 2 further includes a second active portion 22 overlapping the data lines 41, so as to realize an electrical connection between the first active layer 2 and the data lines 41.

In one possible embodiment, as shown in FIG. 1A and FIG. 1C, the display panel further includes a gate structure G located on a side of the first active layer 2 facing away from the substrate 11. The orthographic projection of the gate structure G on the base substrate 11 covers at least part of the third active portion 23. In the specific implementation, the gate structure G can be composed of different structures, which are specified below.

In one possible embodiment, as shown in FIG. 1A and FIG. 1C, the gate line 31 includes the gate portion G1 (as shown in the dash line frame in FIG. 1C). The third active portion 23 includes an overlapping portion D (as shown in the dash line frame in FIG. 1B). The orthographic projection of the overlapping portion D on the base substrate 11 overlaps with the orthographic projection of the gate portion G1 on the base substrate 11. The orthographic projection of the gate structure G on base substrate 11 at least covers the orthographic projection of overlapping portion D on base substrate 11. Specifically, in the structure shown in FIG. 1A, the overlapping portion D can be understood as the region that overlaps the gale line 31 in the third active portion 23, that is the overlapping portion D, as shown in FIG. 1B.

In one possible embodiment, as shown in FIG. 1A, FIG. 2A, FIG. 2B and FIG. 2C, the gate structure G may include only the gate portion G1.

In one possible embodiment, the gate structure G may also include the gate portion G1 and an auxiliary gate G2. Specifically, the material of the gate portion G1 can be the same as the material of the gate line 31. The auxiliary gate G2 can be transparent, and specifically, the materials of the auxiliary gate G2 can include metal oxides (e.g., indium tin oxide, indium-doped zinc oxide (AZO), fluorine-doped tin oxide (AZO), aluminum-doped zinc oxide (AZO), indium-doped cadmium oxide.

For ultra-high-resolution display products, the aperture ratio of the pixel area can be effectively improved by optimizing the line width of the traces and the size of the through holes, so as to optimize the display effect, but at the same time, the impact of the reduction of the channel length also poses corresponding challenges to the short channel characteristics of the transistors in the display backplane. When the channel length is less than 2 μm, the oxide transistor will have obvious short-channel effects, which mainly include the Drain Induced Barrier Lowering (DIBL) effect and the diffusion effect of conductor doping, both of which will affect the characteristics of the oxide transistor, resulting in the unguaranteed characteristics. In the embodiment of the present disclosure, the gate structure G further includes an auxiliary gate G2, and under the premise that the width of the gate line 31 is reduced, on the one hand, the injection of a part of the ions can be blocked during the subsequent conductorization, and the channel length can be extended, so that the characteristics of the oxide transistor can be ensured, and the DIBL effect and the diffusion effect of conductorization doping can be avoided, and on the other hand, the transparent auxiliary gate G2 will not affect the transmittance of the light-transmitting region.

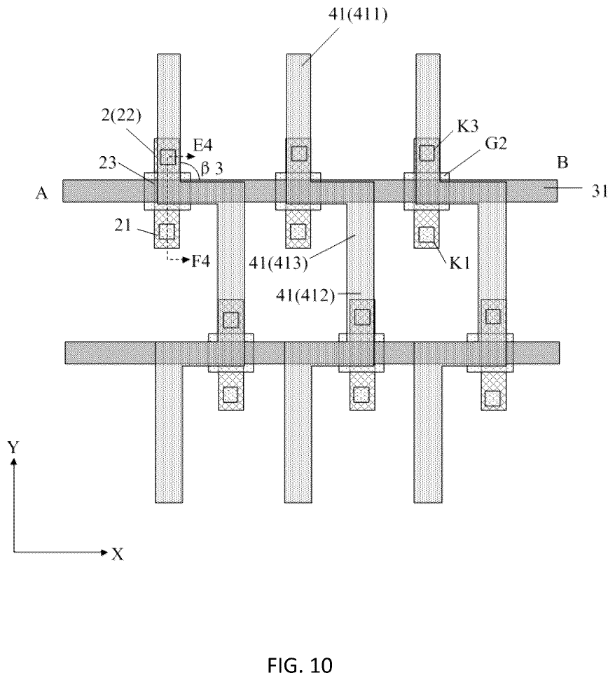

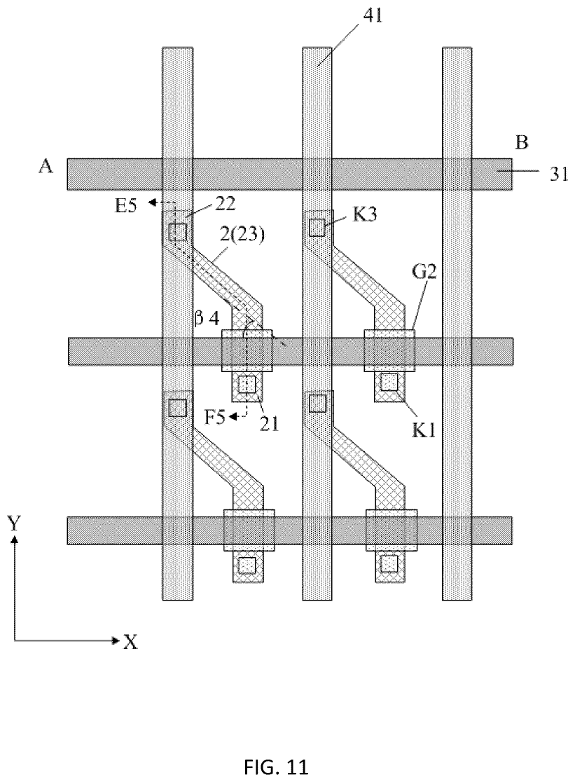

Specifically, the auxiliary gate G2 can be located on a side of the gate portion G1 facing the base substrate 11, or can be located on a side of the gate portion G1 facing away from the base substrate 11, as described below. For example, as shown in FIG. 5, which is a schematic diagram of a cross-section along the dashed line E3F3 in FIG. 9, or a cross-section along the dashed line E4F4 in FIG. 10, or a cross-section along the dashed line E5F5 in FIG. 11. The gate structure G may include a gate portion G1, and an auxiliary gate G2 located on a side of the gate portion G1 facing the base substrate 11. The orthographic projection of the auxiliary gate G2 on the base substrate 11 covers the orthographic projection of the gate portion G1 on the base substrate 11, and covers at least one of regions on both sides of the gate portion G1 in the second direction Y. Specifically, as shown in FIG. 5, the orthographic projection of the auxiliary gate G2 on the BASE substrate 11 covers the orthographic projection of the gate structure G1 on the base substrate 11, and covers regions on both sides of the gate structure G1 in the second direction Y. Specifically, the orthographic projection of the auxiliary gate G2 on the substrate 11 can also be the orthographic projection covering the orthographic projection of the gate structure G1 on the base substrate 11, and covers one of the regions on both sides of the gate structure G1 in the second direction Y.

It should be noted that the first through hole shown in FIG. 5 can also be connected in the same way as shown in FIG. 2A and FIG. 4.

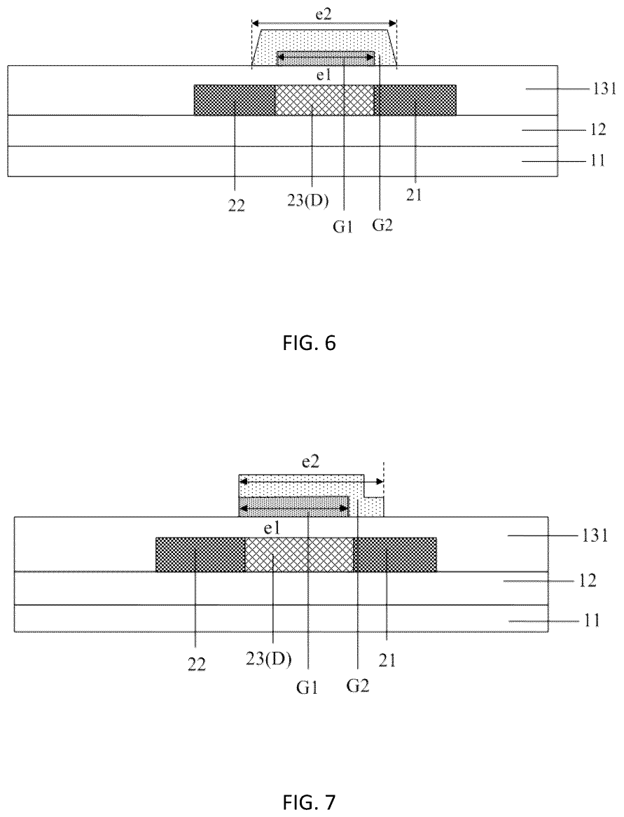

In one possible embodiment, as shown in FIG. 6 and FIG. 7, the gate structure G includes a gate portion G1 and an auxiliary gate G2 located on the side of the gate portion G1 facing away from the base substrate 11. The orthographic projection of auxiliary gate G2 on the base substrate 11 covers the orthographic projection of the gate portion G1 on the base substrate 11, and covers at least one of regions on both sides of the gate portion G1 in the second direction Y. Specifically, as shown in FIG. 6, for example, the orthographic projection of the auxiliary gate G2 on the base substrate 11 convers the orthographic projection of the gate portion G1 on the base substrate 11, and covers the regions on both sides of the gate portion G1 in the second direction Y. Specifically, as shown in FIG. 7, the orthographic projection of the auxiliary gate G2 on the base substrate 11 covers the orthographic projection of the gate portion G1 on the base substrate 11, and covers one of the regions on both sides of the gate portion G1 in the second direction Y.

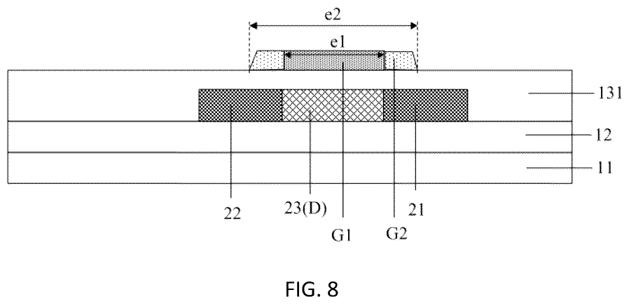

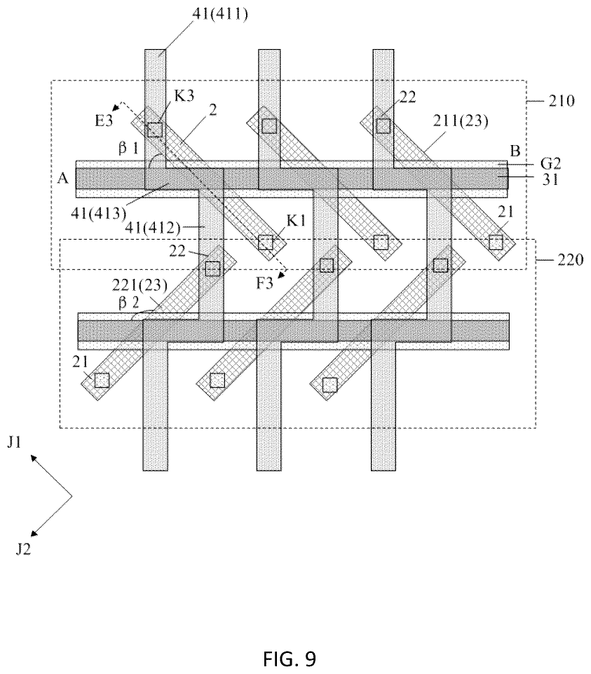

In one possible embodiment, as shown in FIG. 8, the gate structure G includes a gate portion G1 and an auxiliary gate G2 located on both sides of the gate portion G1 in the second direction Y. The orthographic projection of the gate portion G1 on the base substrate 11 does not overlap with the orthographic projection of the auxiliary gate G2 on the base substrate 11. That is, the orthographic projection of the auxiliary gate G2 on the base substrate 11 is located on both sides of the orthographic projection of the gate portion G1 on the base substrate 11.

In one possible embodiment, as shown in FIG. 5 to FIG. 8, the maximum spacing of the orthographic projection of the auxiliary gate G2 on the base substrate 1 in the second direction Y e2 is greater than or equal to the maximum spacing e1 of the orthographic projection of the gate portion G1 on the base substrate 1 in the second direction. It should be noted that for the display panel structure shown in FIG. 5 to FIG. 7, the maximum spacing e2 of the orthographic projection of the auxiliary gate G2 on the base substrate 1 in the second direction Y can be understood as the width of the auxiliary gate G2 in the second direction Y. For the display panel structure shown in FIG. 8, the maximum spacing e2 between the orthographic projection of the auxiliary gate G2 on the base substrate 1 in the second direction Y can be understood as the maximum distance between the two auxiliary gates G2 in the second direction Y.

In the specific embodiment, the first active layer 2 can have a variety of different pattern shapes, which are specified below.

In a possible embodiment, the first active layer 2 may include a plurality of oblique linear patterns, specifically, as shown in FIG. 9, the cross-section along the dashed line E3F3 in FIG. 9 can be shown in FIG. 5, and the gate line 31 extends from the first end A to the second end B along the first direction X. The first active layer 2 includes a first active group 210 and a second active group 220 alternately arranged in the second direction Y. The first active group 210 includes a plurality of first active patterns 211 extending along the third direction J1 and arranged sequentially along the first direction X. The first active patterns 211 include first active portion 21s, second active portions 22 and third active portions 23. The angle β1 formed by a first active pattern 211 and a gate line 31 towards the first end A is an acute angle. The second active group 220 includes a plurality of second active patterns 222 extending along the fourth direction J2 and arranged sequentially along the first direction X. The second active patterns 222 include first active portions 21, second active portions 22 and third active portions 23. The angle β2 formed by a second active pattern 222 and a gate line 31 towards the first end A is an obtuse angle.

In a possible embodiment, the first active layer 2 may include a plurality of (vertical) linear patterns extending along the second direction. Specifically, as shown in FIG. 10, the cross-section along the dashed line E4F4 in FIG. 10 can be as shown in FIG. 5, and the gate lines 31 extend from the first end A to the second end B along the first direction X. The first active portion 21, the second active portion 22, and the third active portion 23 all extend along the second direction Y, and form an angle β3 with the gate lines 31 towards the side of the first end A. the angle β3 is a right angle.

In a possible embodiment, the first active layer 2 may include a plurality of oblique and non-linear patterns. Specifically, as shown in FIG. 1A, FIG. 1B and FIG. 11, the cross-section along the dashed line E5F5 in FIG. 11 can be shown in FIG. 5, and the gate lines 31 extend from the first end A to the second end B along the first direction X. The first active portion 21 and the second active portion 22 extend along the second direction Y, and the extension line of the first active portion 21 does not coincide with the extension line of the third active portion 23. At least part the third active part 23 forms an angle β4 with a gate line 31 towards the first end A. The angle β4 is an acute angle.

In one possible embodiment, the region used to lap with the first electrode 53 in the first active layer 2 can serve as the first active portion 21, the region used to lap with the data line 41 in the first active layer 2 can serve as the second active portion 22, and the remaining region in the first active layer 2 can serve as the third active portion 23, as shown in FIG. 1A to FIG. 11. In a possible embodiment, as shown in FIG. 1A and FIG. 1B, the third active portion 23 includes only a portion extending in one direction, and if only includes a portion extending obliquely, the obliquely extended portion overlaps with the gate line 31 to form at least a part of the channel area (in the embodiment of the present disclosure, the channel area may also include an area formed by the overlapping of the auxiliary gate G2 and the third active portion 23). In another possible embodiment, as shown in FIG. 11, the third active portion 23 may include a plurality of portions with different extension directions, for example, including an oblique extension portion and a vertically extending portion, the vertically extended portion overlaps with the gate line 31 to form at least a part of the channel area (in the embodiment of the present disclosure, the channel area may also include an area formed by the overlapping of the auxiliary gate G2 and the third active portion 23).

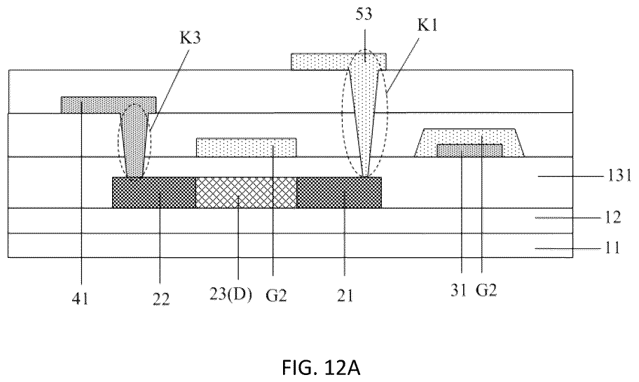

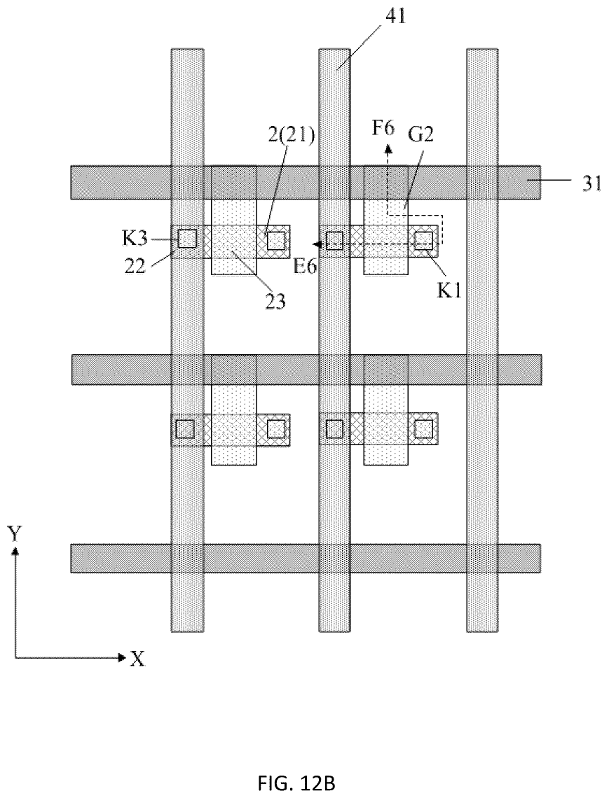

In a possible embodiment, the first active layer 2 may include a (transverse) linear pattern extending along the first direction. Specifically, as shown in FIG. 12A and FIG. 12B, FIG. 12A is a schematic diagram of cross-section along the dashed line E6F6 in FIG. 12B. The first active portion 21, the second active portion 22, and the third active portion 23 all extend along the first direction X, and the orthographic projection of the first active layer 2 on the base substrate 11 has a gap with the orthographic projection of the gate line 31 on the base substrate 11 The third active portion 23 is located in the light-transmitting region P. The gate structure G includes an auxiliary gate G2 located on a side of the first active layer 2 facing away from the base substrate 11. The auxiliary gate G2 extends along the second direction Y, and the orthographic projection of the auxiliary gate G2 on the base substrate 1 covers the orthographic projection of the third active portion 23 on the base substrate 1. Specifically, the gate structure G may only include an auxiliary gate G2. The first gate layer (i.e., the layer where the gate line 31 is located) may be located on a side of the first active layer 2 facing away from the base substrate 11, and the auxiliary gate G2 is located on a side of the gate line 31 facing away from the base substrate 11 and is in contact with the gate line 31. a part of the auxiliary gate G2 overlaps with the third active portion 23 to form a channel area, and the other part of the auxiliary gate G2 overlaps with the gate line 31 to achieve contact lap with the gate line 31. In the embodiment of the present disclosure, a transparent auxiliary gate G2 may be arranged in the light-transmitting region P, and the gate line 31 may only be used as a trace and overlapped with the auxiliary gate G2 in the non-light-transmitting region. Because the channel area of the first active layer 2 and the auxiliary gate G2 are both transparent materials, and the transmittance will not be reduced when the channel area of the first active layer 2 and the auxiliary gate G2 are placed in the light-transmitting region P, so the width of the auxiliary gate G2 can be appropriately increased, so that the transistor characteristics can be further guaranteed.

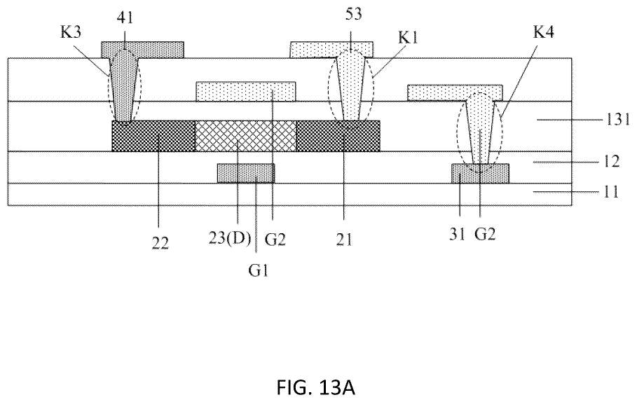

In a possible embodiment, as shown in FIG. 13A and FIG. 13B, FIG. 13A is a schematic diagram of the cross-section along the dashed line E7F7 in FIG. 13B. The gate line 31 further includes a gate-line branch 32 extending along the second direction Y. The orthographic projection of the auxiliary gate G2 on the base substrate 11 covers the orthographic projection of the gate-line branch 32 on the base substrate 11. Specifically, the first gate layer (i.e., the layer where the gate lines 31 are located) can be located on a side of the first active layer 2 facing the base substrate 11, that is, the first gate layer is lowered, the gate-line branch 32 is used as the bottom gate, and the auxiliary gate G2 is overlapped with the bottom gate (gate-line branch 32) through a punched hole (the through hole K4 in FIG. 13B). On the one hand, the control force of the gate can be further enhanced, especially for the part of the back channel area, on the other hand, the gate-line branch 32 is equivalent to adding a shading layer to the oxide transistor to improve the photostability characteristics of the oxide transistor.

In one possible embodiment, the materials of the auxiliary gate G2 include indium tin oxide, indium-doped zinc oxide, fluorine-doped tin oxide, aluminum-doped zinc oxide, or indium-doped cadmium oxide.

In a possible embodiment, as shown in FIG. 9 or FIG. 10, the data line 41 may include a first data portion 411 and a second data portion 412 extending along the second direction Y and alternately arranging along the second direction Y, and a third data portion 413 connecting the first data portion 411, the second data portion 412 and extending along the first direction X. The extension line of the first data portion 411 and the extension line of the second data portion 412 do not coincide.

In one possible embodiment, as shown in FIG. 1A, FIG. 11, FIG. 12B, FIG. 13B, the data line 41 may also be extended only along the second direction Y.

It should be noted that in FIG. 5 to FIG. 13B, in order to clearly illustrate the specific composition of the gate structure G, and the rest of the layers are abbreviated, in the specific implementation, the display panel shown in FIG. 5 to FIG. 13B can also include film layers as shown in FIG. 1A to FIG. 4, and the conduction mode of the first electrode 53 and the first active layer 2 can also be shown as FIG. 1A to FIG. 4.

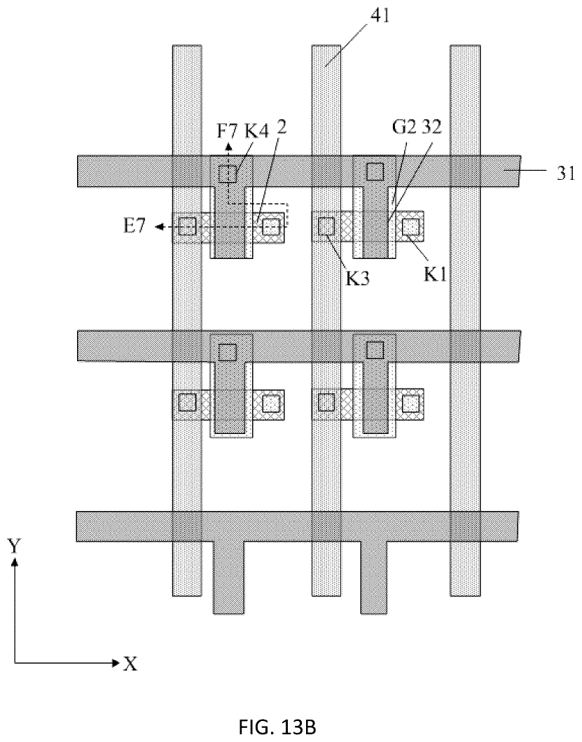

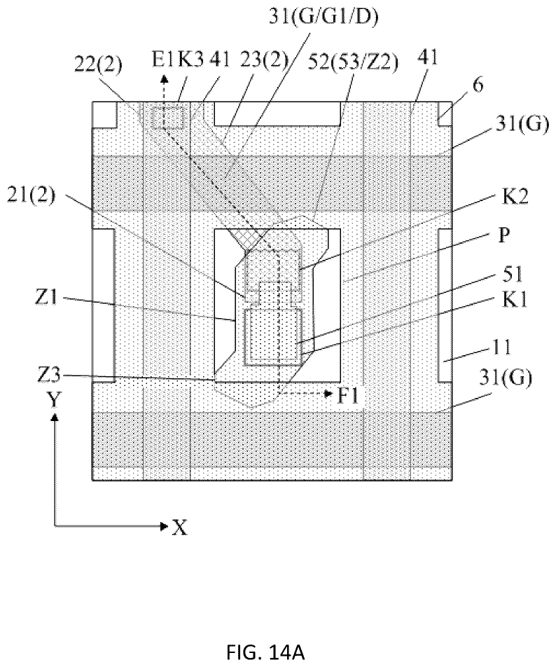

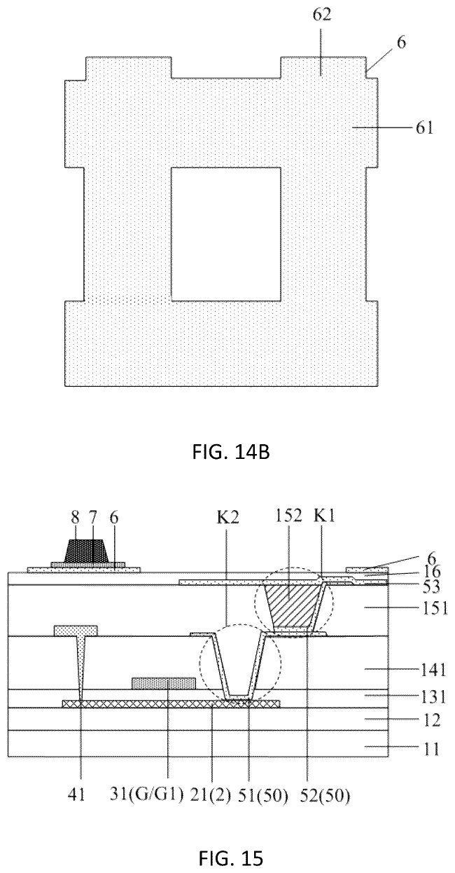

In one possible embodiment, as shown in FIG. 14A and FIG. 14B, FIG. 14B is a schematic diagram of a single layer of the common electrode in FIG. 14A, and the display panel further includes a common electrode 6 located on a side of the first electrode 5 facing away from the base substrate 11. The common electrode 6 includes a first common electrode portion 61 extending along the first direction X, and a second common electrode portion 62 extending along the second direction Y. The orthographic projection of the first common electrode portion 61 on the base substrate 11 covers the orthographic projection of the gate line 31 on the base substrate 11, and the orthographic projection of the second common electrode portion 62 on the base substrate 11 covers the orthographic projection of the data line 41 on the base substrate 11. The orthographic projection of the first through hole K1 on the base substrate 11 is located in the orthographic projection of an area where the first common electrode portion 61 intersects with the second common electrode portion 62 on the base substrate. In one possible embodiment, the orthographic projection of the second through hole K2 on the base substrate 11 is also located in the orthographic projection of the area where the first common electrode portion 61 intersects with the second common electrode portion 62 on the base substrate. In the embodiment of the present disclosure, the first electrode 53 is designed as a strip, and the common electrode 6 is designed as a mesh. It can be seen through a simulation that the display panel of the present embodiment can significantly improve the efficiency of the liquid crystal, and the efficiency of the liquid crystal can be increased from 54.2% of the conventional design to 58.4%.

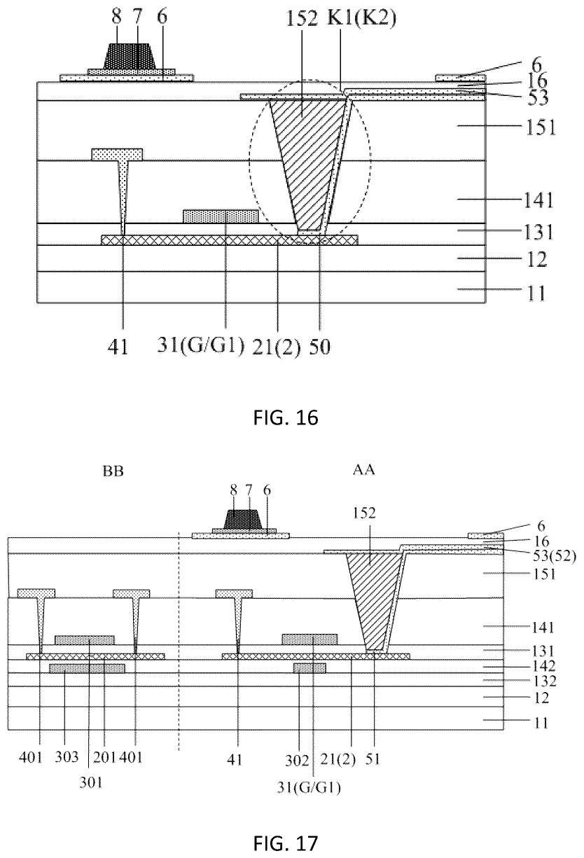

In one possible embodiment, as shown in FIG. 15 and FIG. 16, the display panel further includes a first shading layer 7 located on a side of the common electrode 6 facing away from the first electrode 53 and in direct contact with the common electrode 6, and a spacer 8 located on a side of the first shading layer 7 facing away from the first electrode layer 53. The orthographic projection of the common electrode 6 on the base substrate 11 covers the orthographic projection of the first shading layer 7 on the base substrate 11, and the line width of the first shading layer 7 is smaller than the line width of the common electrode 6. The orthographic projection of the first shading layer 7 on the base substrate 11 covers the orthographic projection of the spacer 8 on the base substrate 11, and the line width of the spacer 8 is smaller than the line width of the first shading layer 7.

Specifically, the first shading layer 7 may be made of blackened metal material, the spacer 8 may be made of molybdenum or aluminum (i.e., a material that can be wet-etched). The first shading layer 7 and the spacer 8 can be formed through one mask process. By means of wet etching and dry etching, and the difference of etching bias (bias) of the spacer 8 and the first shading layer 7 is used to make the first shading layer 7 and the spacer 8 form a step shape.

Specifically, the thickness of the first shading layer 7 can be 30 nm to 80 nm, and the thickness of the spacer 8 can be 0.4 μm to 1 μm. The first shading layer 7 can be used for shielding the gate line 31 and the data line 41 on the one hand, and on the other hand, the resistance of the common electrode 6 can be reduced.

In a possible embodiment, the orthographic projection of the first shading layer 7 on the base substrate 11 covers the orthographic projection of the data line 41 on the base substrate 11, and convers the orthographic projection of the gate line 31 on the base substrate 11. The orthographic projection of the spacer 8 on the base substrate 11 covers the orthographic projection of the data line 41 on the base substrate 11, and covers the orthographic projection of the gate line 31 on the base substrate 11.

Specifically, the shape of the first shading layer 7 and the spacer 8 can be similar to the pattern shape of the common electrode 6 shown in FIG. 14A, that is, the first shading layer 7 may include a first shading portion extending along the first direction X and a second shading portion extending along the second direction Y, and the first shading portion and the second shading portion cross to form a mesh structure. The spacer 8 may include a first spacer extending along the first direction X, and a second spacer extending along the second direction Y, and the first spacer and the second spacer cross to form a mesh structure. The spacer 8 of the mesh structure can be designed with a narrow line width, which is conducive to improving the aperture ratio of the display panel.

In one possible embodiment, as shown in FIG. 17 to FIG. 20, the display panel further includes a gate drive circuit located at a non-display area BB. The gate drive circuit includes a first driving active layer 201, a first driving gate 301 located on a side of the first driving active layer 201 facing away from the base substrate 11, and a first driving source-drain 401 located on a side of the first driving gate 301 facing away from the first driving active layer 201.

In one possible embodiment, as shown in FIG. 17, the first driving active layer 201 is arranged on a layer same as a layer where the first active layer is located, and of the material same as material of the first active layer 2. The first driving gate 301 is located on a layer same as a layer where the first gate layer is located and of the material same as the material of the first gate layer, that is, the first driving gate 301 is located on the layer same as a layer where the gate line 31 is located, and of the material same as the material of the gate line 31. The first driving source-drain 401 is located on a layer same as a layer where the first source-drain layer is located, and of the material same as the material of the first source-drain layer, that is, the first driving source-drain 401 is located on a layer same as a layer where the data line 41 is located, and of the material same as the material of the data line 41. Specifically, the first active layer 2 and the first driving active layer 201 can be oxide active layers, specifically, the material of the first active layer 2 may include amorphous indium gallium zinc oxide material (a-IGZO), zinc nitrogen oxide (ZnON), or indium zinc tin oxide (IZTO). In the embodiment of the disclosure, the corresponding film layers of the display area AA and the non-display area BB are located on the same layer and of the same material, and each film layer corresponding to the non-display area can be formed at the same time as each film layer of the display area AA, so that the manufacturing process of the display panel can be simplified.

In one possible embodiment, as shown in FIG. 17, the display panel further includes a second gate layer located between the base substrate 11 and the first active layer 2. The second gate layer includes a first gate 302 located in the display area AA, and a second driving gate 303 located in the non-display area BB. The orthographic projection of the gate line 31 on the base substrate 1 covers the orthographic projection of the first gate 302 on base the substrate 11. The orthographic projection of the second driving gate 303 on the base substrate 11 covers the orthographic projection of the first driving gate 301 on the base substrate 11. In the embodiment of the disclosure, when an oxide active layer is used for both the active layer of the transistors in the display area and the non-display area, an oxide double-gate structure is adopted for the transistors of the gate driving circuit in the non-display area, and the bottom gate size is larger than the top gate size (the unilateral wrapping size can be 0.5 μm to 2 μm), which can effectively improve the on-state current of the transistor and the stability of the device. For transistors in the light-transmitting region, the bottom gate size is smaller than the top gate size (a spacing distance between a side of the bottom gate and a side of the top gate adjacent to the side of the bottom gate is 0.3 μm to 0.6 μm), which can avoid the influence on the aperture ratio.

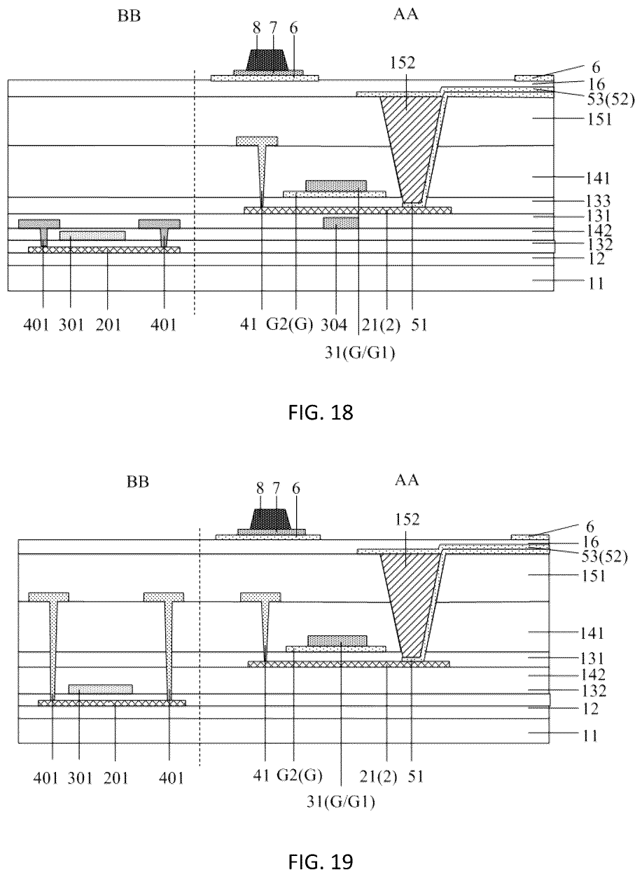

In one possible embodiment, as shown in FIG. 18, the display panel further includes a second gate 304 located in the display area AA and between the base substrate 11 and the first active layer 2. The first driving source-drain 401 and the second gate 304 are on the same layer and of the same material. The material of the first driving active layer 201 includes polysilicon. In the embodiment of the present disclosure, considering that the current design of the high-migration oxide gate drive circuit is not mature enough, and the size of the transistors in the gate drive circuit is large, resulting in an excessively large bezel, in the embodiment of the present disclosure, a low-temperature polycrystalline silicon transistor design may be used in the gate drive circuit. The first driving source-drain 401 of the low-temperature polycrystalline silicon transistor is on a layer same as a layer where the bottom gate (the second gate 304) of the transistor in the display area, which are formed by one mask process, and the manufacturing process of the display panel can be simplified. Moreover, the bottom gate (the second gate 304) of the display area is designed to shade the first active layer 2 of the oxide in the display area, so as to improve the stability of the transistors in the display area.

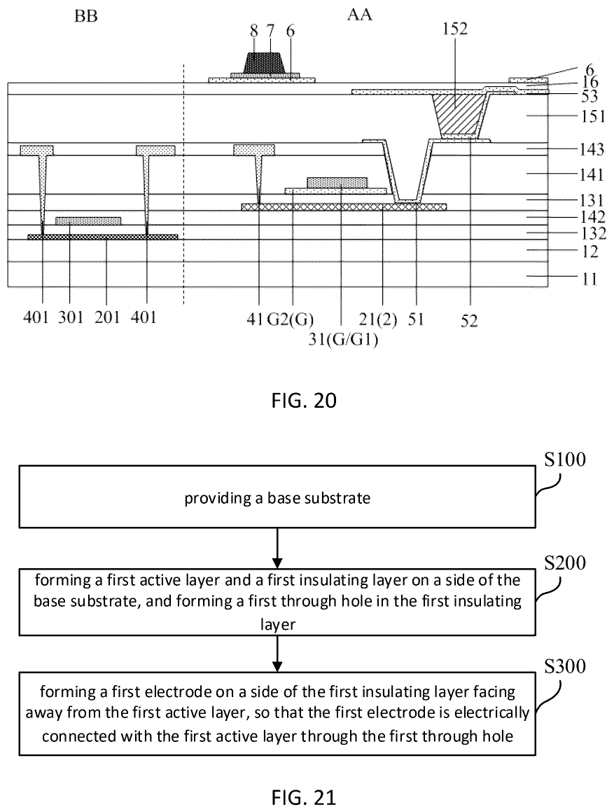

In one possible embodiment, as shown in FIG. 19 and FIG. 20, the first driving source-drain 401 and the first source-drain layer are on the same layer and of the same material, that is, the first driving source-drain 401 and the data line 41 are on the same layer and of the same material. The material of the first driving active layer 201 includes polysilicon. Specifically, in the embodiment of the present disclosure, the first active layer 2 of the transistors in the display area may adopt an oxide active layer. The transistors in the non-display area may adopt a polycrystalline silicon active layer. The oxide thin-film transistors have the advantages such as low leakage current, the low-temperature polycrystalline silicon thin-film transistors have the advantages of high mobility and fast charging. The low-temperature polycrystalline silicon thin-film transistor and the oxide thin-film transistor are integrated on a display panel to form a low-temperature polycrystalline oxide display panel, and the advantages of both can be used to achieve high resolution (Pixel Per Inch, PPI), low-frequency drive, which can reduce power consumption and improve display quality. In addition, in the embodiment of the present disclosure, the first driving source-drain 401 and the first source-drain layer are on the same layer and of the same material, so that the manufacturing process of the display panel can be simplified.

Specifically, in conjunction with FIG. 1A to FIG. 20, the display panel further includes at least one of the following:
a second interlayer dielectric layer 142 located between the base substrate 11 and the first active layer 2;
a first gate insulating layer 132 located between the second interlayer dielectric layer 142 and the base substrate 11;
a buffer layer 12 located between the first gate insulating layer 132 and the base substrate 11;
a second gate insulating layer 131 located between the first active layer 2 and the gate portion G1;
a third gate insulating layer 133 located between the second gate insulating layer 131 and the second insulating layer 141;
a third interlayer dielectric layer 143 located between the first connecting sub-electrode 51 and the second insulating layer 141; and
a passivation layer 53 located on a side of the first electrode 53 facing away from the third insulating layer 152.

In some examples, the buffer layer 12, the first insulating layer 151, the second insulating layer 141 and the third insulating layer 153 may be inorganic insulating layers, for example, the buffer layer 12, the first insulating layer 151, the second insulating layer 141 and the third insulating layer 153 may adopt any one or more of the silica oxide (SiOx), silicon nitride (SiNx) and silicon nitride (SiON), which may be a single layer, multiple layers or composite layers. The first gate layer, the first source-drain layer, the second gate, and the second source-drain layer can be made of metal materials, such as at least one of silver (Ag), copper (Cu), aluminum (Al), titanium (Ti) or molybdenum (Mo), or can be made of alloy materials of the above metals, such as aluminum neodymium alloy (AlNd) or molybdenum-niobium alloy (MoNb), which can be a single-layer structure, or a multi-layer composite structure, such as Ti/Al/Ti, etc.

Based on the same invention conception, some embodiments of the present disclosure also provide a display device, which includes a display panel provided in the embodiments of the present disclosure.

Based on the same invention conception, as shown in FIG. 21, some embodiments of the present disclosure also provide a method for manufacturing a display panel provided in the embodiments of the present disclosure, wherein, including:
step S100, providing a base substrate, specifically, the base substrate can be a glass substrate; in some embodiments, the buffer layer can be deposited on a side of the base substrate, and the material of the buffer layer is SiN/SiO₂, and the thickness range thereof can be 200 nm to 500 nm;
step S200, forming a first active layer and a first insulating layer on a side of the base substrate, and forming a first through hole in the first insulating layer; specifically, the active layer of metal oxides resistant to light can be deposited, and the material thereof can be rare earth-doped IZO or IGZO and other materials, which can make the transistor characteristics stable under light, and the thickness thereof is 20 nm to 50 nm; after that, the second gate insulating layer 131 can be deposited, the material thereof is SiO₂, the thickness thereof can be 100 nm to 150 nm, and then the first gate layer is deposited, the material thereof can be Al, Ti or Mo, Cu and other materials, the thickness thereof can be 200 nm to 500 nm, the first gate layer is photoetched and etched to form the gate line and the shape of the gate portion; after that, the second insulating layer 141 is deposited, and the material thereof can be SiO₂/SiN, with a thickness of 300 nm to 500 nm, and then a through hole are opened in the second insulating layer 141; after that, the first source-drain layer is deposited, and the material thereof can be selected to be similar to that of the gate line, and then the first source-drain layer is patterned; after that, a through hole is opened in the light-transmitting region to form a second through hole K2 connected with the second active layer 2, and then the first connecting sub-electrode 51 layer is deposited in the second through hole K2 for patterning. After that, the first insulating layer 151 is deposited, the segment difference of the second through hole K2 and the metal in the lower layer are planarized, and then the first through hole K1 is opened in the light-transmitting region;
step S300, forming a first electrode on a side of the first insulating layer facing away from the first active layer, so that the first electrode is electrically connected with the first active layer through the first through hole. In some embodiments, a second connecting sub-electrode 52 in contact with the first connecting sub-electrode 51 is deposited in the first through hole K1; after that, the filling and leveling up process is carried out through the third insulating layer 152, and the gluing and ashing scheme is adopted to ensure that the segment difference between the filled and leveled-up third insulating layer 152 and the first insulating layer 151 is within 0.2 μm, reducing light leakage, then the first electrode 53 at the position of the through hole in the light-transmitting region is covered to shield the electric field in the through hole, then continuing to complete the deposition of the passivation layer 16 and the common electrode 6; after that, the first shading layer 7 and the spacer 8 are deposited, the first shading layer 7 is made of blackened metal material, and the spacer 8 is made of metal Mo or Al and other materials that can be wet-etched, the first shading layer 7 and the spacer 8 are formed by one mask process; the thickness of the first shading layer 7 is 30 nm to 80 nm, the thickness of the spacer 8 is 0.4 μm to 1 μm, and the difference between the spacer 8 and the first shading layer 7 etching bias is used to form the wrapping relationship between the first shading layer 7 and the spacer 8.

In one possible embodiment, with respect to step S200, forming the first active layer and a first insulating layer on the side of the base substrate, includes:
step S211, forming a second insulating layer on a side of the first active layer facing away from the base substrate, and forming an exposed second through hole in the second insulating layer;
step S212, forming a first connecting sub-electrode in a region where the second through hole is located;
step S213, forming a first insulating layer on a side of the second insulating layer facing away from the first active layer, and forming a first through hole in the first insulating layer;
step S214, forming a second connecting sub-electrode in a region where the first through hole is located;
step S215, filling a region of the second connecting sub-electrode facing away from the first connecting sub-electrode and at a position in the first through hole.

In one possible embodiment, with respect to step S200, forming a first active layer and a first insulating layer on a side of the base substrate, includes:
step S221, forming a second insulating layer on a side of the first active layer facing away from the base substrate;
step S222, forming a first insulating layer on a side of the second insulating layer facing away from the first active layer;
step S223, forming a first through hole through the first insulating layer and a second through hole penetrating through the second insulating layer and exposing a part of the first active layer through one patterning process;
step S224, forming a connecting electrode in regions where the second through hole and the first through hole are located;
step S225, filling the regions of the connecting electrode on a side facing away from the first active layer and located in the second through hole and the first through hole.

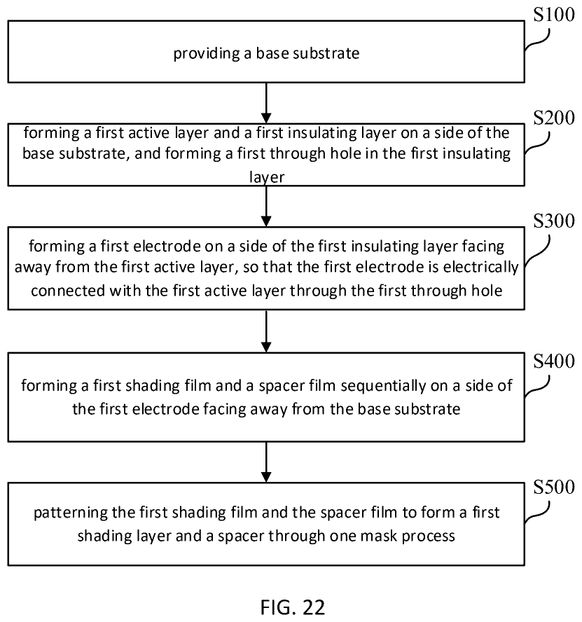

In one possible embodiment, as shown in FIG. 22, after step S300, the manufacturing method further includes:
step S400, forming a first shading film and a spacer film sequentially on a side of the first electrode facing away from the base substrate;
step S500, patterning the first shading film and the spacer film to form a first shading layer and a spacer through one mask process.

Although preferred embodiments of the present disclosure have been described, those embodiments may be subject to additional changes and modifications once the basic inventive concepts are known to those skilled in the art. Therefore, the attached claims are intended to be construed to include the preferred embodiments and all changes and modifications that fall within the scope of the disclosure.

Obviously, a person skilled in the art may make various changes and variants to the embodiments of the present disclosure without departing from the spirit and scope of the embodiments of the present disclosure. Thus, if these modifications and variants of the embodiments of the present disclosure fall within the scope of the claims of the present disclosure and their equivalents, the present disclosure is also intended to include these modifications and variants.

1.-38. (canceled)

39. A display panel with a display area comprising a plurality of light-transmitting regions and a non-display area located at a periphery of the display area, wherein the display panel comprises:
a base substrate;
a first transistor, located in the display area on a side of the base substrate, and comprising a first active layer;
a first electrode, located on a side of the first active layer facing away from the base substrate;
a first insulating layer, located between the first active layer and the first electrode, and being in contact with the first electrode,
wherein the first insulating layer is provided with a first through hole penetrating the first insulating layer, and an orthographic projection of the first through hole on the base substrate is located in an orthographic projection of the light-transmitting regions on the base substrate, the first electrode is electrically connected with the first active layer through the first through hole.

40. The display panel of claim 39, further comprising:
a second insulating layer located between the first insulating layer and the first active layer, wherein the second insulating layer is provided with a second through hole;
a connecting electrode between the first electrode and the first active layer, wherein a part of the connecting electrode is located on a side of the first insulating layer facing away from the base substrate, and is in contact with the first electrode;
wherein the first electrode is electrically connected with the first active layer through the connecting electrode at the second through hole and the first through hole.

41. The display panel of claim 40, wherein an orthographic projection of the second through hole on the base substrate is located in the orthographic projection of the light-transmitting regions on the base substrate;
wherein the first active layer comprises a first active portion, and the first active portion is located in the light-transmitting regions; the first electrode is electrically connected with the first active part through the first through hole.

42. The display panel of claim 40, further comprising:
a plurality of signal lines extending along a first direction;
wherein the orthographic projection of the first through hole on the base substrate and an orthographic projection of the second through hole on the base substrate are located between an orthographic projection of a N^{th} signal line on the base substrate and an orthographic projection of a (N+1)^{th} signal line on the base substrate;
in a direction perpendicular to the first direction, the orthographic projection of the first through hole on the base substrate is on a side of the orthographic projection of the second through hole on the base substrate facing away from the N^{th} signal line, wherein N is a positive integer;
wherein the connecting electrode comprises:
a first connecting sub-electrode located between the second insulating layer and the first insulating layer, and
a second connecting sub-electrode between the first electrode and the first insulating layer;
wherein a part of the first connecting sub-electrode is located at a bottom of the second through hole and is in contact with the first active layer at the bottom of the second through hole; a part of the first connecting sub-electrode extends to a bottom of the first through hole on a side of the second insulating layer facing away from the base substrate, and is in contact with the second connecting sub-electrode at the bottom of the first through hole;
a part of the second connecting sub-electrode is located at the bottom of the first through hole and is in contact with the first connecting sub-electrode at the bottom of the first through hole; a part of the second connecting sub-electrode extends to a side of the first insulating layer facing away from the base substrate and is in contact with the first electrode;
wherein the display panel further comprises a third insulating layer filled in the first through hole,
wherein a segment difference between a surface of the third insulating layer facing away from the base substrate and a surface of the first insulating layer facing away from the base substrate is less than 0.2 μm.

43. The display panel of claim 40, wherein the orthographic projection of the first through hole on the base substrate covers the orthographic projection of the second through hole on the base substrate; one end of the connecting electrode is directly in lap-contact with the first active layer, and the other end of the connecting electrode is directly in lap-contact with the first electrode.

44. The display panel of claim 43, further comprising:
a third insulating layer filled in the second through hole and the first through hole,
wherein a segment difference between a surface of the third insulating layer facing away from the base substrate, and the a surface of the first insulating layer facing away from the base substrate is less than 0.2 μm.

45. The display panel of claim 39, wherein a material of the first active layer comprises a metal oxide doped with rare earth elements;
wherein a material of the auxiliary gates comprise indium tin oxide, indium-doped zinc oxide, fluorine-doped tin oxide, aluminum-doped zinc oxide, or indium-doped cadmium oxide;
wherein a material of the first shading layer comprises blackened metal; a material of the spacer comprises molybdenum or aluminum.

46. The display panel of claim 40, wherein an orthographic projection of the first electrode on the base substrate covers the orthographic projection of the first through hole on the base substrate and the orthographic projection of the second through hole on the base substrate.

47. The display panel of claim 41, further comprising:
a first gate layer, and
a first source-drain layer;
wherein the first gate layer comprises the signal lines, and the signal lines comprise gate lines; the first source-drain layer comprises a plurality of data lines of which main bodies extend along a second direction;
wherein the first active layer further comprises a second active portion, and a third active portion connecting the first active portion with the second active portion; an orthographic projection of the second active portion on the base substrate partially overlaps with orthographic projections of the data lines on the base substrate;
wherein the second insulating layer is further provided with a third through hole, and the data lines are electrically connected with the second active portion through the third through hole;
wherein the display panel further comprises a gate drive circuit located in the non-display area, and the gate drive circuit comprises a first driving active layer, a first driving gate, and a first driving source-drain;
wherein the display panel further comprises:
a gate structure located on a side of the first active layer facing away from the base substrate,
wherein an orthographic projection of the gate structure on the base substrate covers an orthographic projection of at least part of the third active portion on the base substrate;
wherein the gate lines comprise gate portions; the third active portion comprises an overlapping portion, wherein an orthographic projection of the overlapping portion on the base substrate overlaps with orthographic projections of the gate portions on the base substrate;
wherein the orthographic projection of the gate structure on the base substrate at least covers the orthographic projection of the overlapping portion on the base substrate.

48. The display panel of claim 47, wherein the gate structure comprises:
auxiliary gates arranged at a side of the gate portions facing the base substrate;
wherein orthographic projections of the auxiliary gates on the base substrate cover the orthographic projections of the gate portions on the base substrate, and covers at least one of two sides of the gate portions in the second direction; or
the gate structure comprises:
auxiliary gates arranged at a side of the gate portions facing away from the base substrate;
wherein orthographic projections of the auxiliary gates on the base substrate covers the orthographic projections of the gate portions on the base substrate, and covers at least one of two sides of the gate portions in the second direction; or
the gate structure comprises:
the gate portions, and
auxiliary gates located at two sides of the gate portions in the second direction,
wherein the orthographic projections of the gate portions on the base substrate do not overlap with the orthographic projections of the auxiliary gates on the base substrate.

49. The display panel of claim 48, wherein a maximum spacing of orthographic projections of the auxiliary gates on the base substrate in the second direction is greater than or equal to a maximum spacing of orthographic projections of the gate portions on the base substrate in the second direction.

50. The display panel of claim 47, wherein the gate lines extend from a first end to a second end along the first direction; the first active layer comprises a first active group and a second active group alternately arranged in the second direction;
wherein the first active group comprises a plurality of first active patterns extending along a third direction and arranged sequentially along the first direction, the first active patterns comprise the first active portion, the second active portion and the third active portion; an angle between the first active patterns and the gate lines toward the first end is an acute angle;
wherein the second active group comprises a plurality of second active patterns extending along a fourth direction and arranged sequentially along the first direction, the second active patterns comprise the first active portion, the second active portion and the third active portion; an angle between the second active patterns and the gate lines toward the first end is an obtuse angle; or
the gate lines extend from a first end to a second end along the first direction;
wherein the first active portion, the second active portion, and the third active portion all extend along the second direction, and an angle formed by each of the first active portion, the second active portion, and the third active portion with the gate lines toward the first end is a right angle; or
the gate lines extend from a first end to a second end along the first direction;
wherein the first active portion and the second active portion extend along the second direction, and an extension line of the first active portion does not coincide with an extension line of the third active portion; an angle between at least a part of the third active portion and the gate lines toward the first end is an acute angle.

51. The display panel of claim 47, wherein the first active portion, the second active portion, and the third active portion all extend along the first direction, and gaps are arranged between an orthographic projection of the first active layer on the base substrate and orthographic projections of the gate lines on the base substrate;
wherein the third active portion is located in the light-transmitting regions;
wherein the gate structure comprises auxiliary gates located at a side of the first active layer facing away from the base substrate, the auxiliary gates extend along the second direction, and orthographic projections of the auxiliary gates on the substrate cover an orthographic projection of the third active portion on the base substrate, and cover orthographic projections of a part of the gate lines on the base substrate;
wherein the first gate layer is located on a side of the first active layer facing the base substrate; the gate lines further comprise gate-line branches extending along the second direction; the orthographic projections of the auxiliary gates on the base substrate cover orthographic projections of the gate-line branches on the base substrate.

52. The display panel of claim 47, wherein the data lines comprise:
a first data portion and a second data portion, which extend along the second direction and are alternately arranged along the second direction, and
a third data portion connecting the first data portion with the second data portion and extending along the first direction,
wherein an extension line of the first data portion does not coincide with an extension line of the second data portion.

53. The display panel of claim 47, further comprising:
common electrodes located on a side of the first electrode facing away from the base substrate;
wherein the common electrodes comprise:
first common electrode portions extending along the first direction, and
second common electrode portions extending along the second direction;
wherein orthographic projection of the first common electrode portions on the base substrate cover orthographic projections of the gate lines on the base substrate, and orthographic projections of the second common electrodes on the base substrate cover the orthographic projections of the data lines on the base substrate;
wherein the orthographic projection of the first through hole on the base substrate is located in an orthographic projection of a region enclosed by the first common electrodes and the second common electrodes intersecting with each other on the base substrate;
wherein the display panel further comprises:
a first shading layer located on a side of the common electrodes facing away from the first electrode and being in direct contact with the common electrodes, and
a spacer located on a side of the first shading layer facing away from the first electrode layer;
wherein the orthographic projections of the common electrodes on the base substrate, cover an orthographic projection of the first shading layer on the base substrate, and a line width of the first shading layer is smaller than a line width of the common electrodes; the orthographic projection of the first shading layer on the base substrate covers an orthographic projection of the spacer on the base substrate, and a line width of the spacer is smaller than the line width of the first shading layer.

54. The display panel of claim 53, wherein the orthographic projection of the first shading layer on the base substrate covers the orthographic projections of the data lines on the base substrate and covers the orthographic projections of the gate lines on the base substrate;
wherein the orthographic projection of the spacer on the base substrate covers the orthographic projections of the data lines on the base substrate, and covers the orthographic projections of the gate lines the base substrate.

55. The display panel of claim 47, wherein the first driving active layer and the first active layer are on a same layer; the first driving gate and the first gate layer are on a same layer; the first driving source-drain and the first source-drain layer are on a same layer;
wherein the display panel further comprises:
a second gate layer located between the base substrate and the first active layer;
wherein the second gate layer comprises:
a first gate in the display area, and
a second driving gate in the non-display area;
wherein the orthographic projections of the gate lines on the base substrate cover an orthographic projection of the first gate on the base substrate; an orthographic projection of the second driving gate on the base substrate covers an orthographic projection of the first driving gate on the base substrate.

56. The display panel of claim 47, further comprising:
a second gate located in the display area and between the base substrate and the first active layer;
wherein the first driving source-drain and the second gate are on a same layer and of a same material; a material of the first driving active layer comprises polysilicon; or
the first driving source-drain and the first source-drain layer are on a same layer; a material of the first driving active layer comprises polysilicon.

57. The display panel of claim 39, further comprising:
a gate structure comprising a first gate and a second gate; wherein the first gate is located on a side of the first active layer facing the base substrate, and the second gate is located on a side of the first active layer facing away from the base substrate;
wherein an orthographic projection of the first gate is within an orthographic projection of the second gate.

58. the display panel of claim 57, wherein a spacing distance between a side of the first gate and a side of the second gate adjacent to the side of the first gate is 0.3 μm to 0.6 μm.
